(19) United States
(12) Patent Application Publication
(10) Pub. No.: US 2009/0073158 A1
(43) Pub. Date: Mar. 19, 2009

(54) SEMICONDUCTOR ELEMENT AND DEVICE USING THE SAME

(75) Inventors: Kotaro Kataoka, Nara (JP); Hiroshi Iwata, Nara (JP); Yoshiji Ohta, Osaka (JP); Kenji Kimoto, Nara (JP); Kenji Komiya, Sunnyvale, CA (US); Kouichiro Adachi, Nara (JP); Akihide Shibata, Santa Clara, CA (US); Masatomi Harada, Kyoto (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA, Osaka-shi (JP)

(21) Appl. No.: 12/212,303

(22) Filed: Sep. 17, 2008

(30) Foreign Application Priority Data
Sep. 18, 2007 (JP) 2007-241162
Sep. 18, 2007 (JP) 2007-241180

(51) Int. Cl. G09G 5/00; H01L 29/792; G05F 1/10

(52) U.S. Cl. 345/212; 257/324; 327/535; 257/E29.309

(57) ABSTRACT

A memory element having a large memory window and a high reliability is provided at low cost by performing high speed write and erase operations at a relatively low voltage and suppressing rewrite degradation. A memory element includes a semiconductor layer arranged on an insulating substrate, a first diffusion layer region and a second diffusion layer region having a conductivity type of P-type, a charge accumulating film for covering a channel region between the first diffusion layer region and the second diffusion layer region and being injected with charges from the channel region, and a gate electrode positioned on a side opposite to the channel region with the charge accumulating film in between.

### CROSS-REFERENCE TO RELATED APPLICATION

This application is related to Japanese Patent Application No. 2007-241162 filed on Sep. 18, 2007, and Japanese Patent Application No. 2007-241180 filed on Sep. 18, 2007 whose priorities are claimed and the disclosure of which is incorporated by reference in its entirety.

### BACKGROUND OF THE INVENTION

1. Field of the Invention

The present invention relates to a semiconductor element, a driving method, and a semiconductor device including a drive circuit of the semiconductor element. More specifically, the present invention relates to a semiconductor element for accumulating charges in an insulating body having a level for trapping charges, a driving method, and a device equipped with a drive circuit of the semiconductor element such as display device, liquid crystal display device and receiver.

2. Description of Related Art

A semiconductor memory element is generally formed using a semiconductor substrate. A device using an insulating substrate such as glass substrate as in a liquid crystal display device has a semiconductor layer formed on the insulating substrate, and a thin-film transistor (TFT) formed using the semiconductor layer. A signal processing circuit and a device drive circuit are configured by the TFT. A memory element is desirably formed simultaneously on the insulating substrate with the TFT configuring such circuits.

For instance, “CSID 05 Digest”, p. 1152-1155, 2005 by Hung-Tse Chen et al., discloses a non-volatile memory element using a silicon nitride film formed on an insulating substrate such as glass substrate.

FIG. 28 is a frame format view showing a semiconductor storage device disclosed in the above “SID 05 Digest” publication. In the figure, 901 is an insulating substrate made of glass, 902 is a base insulating film, 911 is a silicon semiconductor layer, 921 is a bottom insulating film, 922 is a charge trap insulating film (silicon nitride), 923 is a top insulating film, and 931 is a control gate. Diffusion layer regions 912 and 913 in which N-type impurities are doped to high concentration are formed in the semiconductor layer 911 on both sides of the control gate 931. In this configuration, a gate insulating film functioning as a memory storage unit has an ONO (Oxide-Nitride-Oxide) structure. Storing information are written by applying high electric field between the gate electrode 931 and the diffusion layer regions 912, 913, and injecting charges to the charge trap insulating film 922 from the silicon semiconductor layer 911 by the Fowler-Nordheim (FN) tunneling current. A threshold value of the memory element or an electric field-effect transistor changes by the magnitude in the amount of charges accumulated in the charge trap insulating film 922. The storing information is read out by detecting change in the threshold value.

As described in the above “SID 05 Digest” publication, the injection and drawing of electrons to the charge trap insulating film 922 are performed using the FN tunneling current in write and erase in the technique of forming the non-volatile memory on the insulating substrate made of glass. There is thus is a problem in that high voltage is required for the write and/or erase (write/erase) operation. In the above “SID 05 Digest” publication, high voltage of 20 V is applied in write and −40 V in erase. A power supply or a booster circuit for supplying such high voltage for write/erase thus becomes necessary, which increases the manufacturing cost.

If the write/erase voltage is lowered, on the other hand, the efficiency of the FN tunneling drastically lowers, the write/erase speed significantly lowers, and a sufficient memory window cannot be obtained.

A memory element having a structure shown in FIG. 29 is proposed (Szu-I Hsieh et al., “IEEE ELECTRON DEVICE LETTERS” pgs. 272-274, VOL. 27, No. 4, April, 2006 in order to compensate for the lowering in the write/erase speed. In such memory element, a grain boundary part 941 is formed at a predetermined position in a silicon semiconductor layer 911, and a projection 942 is formed on the surface of the silicon semiconductor layer 911 at the relevant site. In this memory element as well, the write/erase operation is performed by applying high electric field between a gate electrode 931 and N-type diffusion layer regions 912, 913 and injecting charges through the FN tunneling current from the silicon semiconductor layer 911 to the charge trap insulating film 922.

In particular, since such memory element has the projection 942 formed on the surface of the silicon semiconductor layer 911, the electric field concentrates at the portion of the projection 942, and the tunneling of the charges to the charge trap insulating film 922 at the relevant site is promoted. Thus, write/erase operation becomes possible at a lower voltage compared to the semiconductor storage device of the above “SID 05 Digest” publication, in which the projection 942 is not arranged. Furthermore, write/erase at a lower voltage can be performed by performing write/erase using hot carriers in the memory element of FIG. 29.

In Hung-Tse Chen et al., “IEEE ELECTRON DEVICE LETTERS” p 499-501, VOL. 28, No. 6, June 2007, a grain boundary is formed at a predetermined position in the semiconductor layer 911 and the projection is formed on the surface as in “IEEE ELECTRON DEVICE LETTERS” pgs. 272-274, VOL. 27, No. 4, April, 2006, the memory element is arranged to an NAND type, and write and erase are performed using the FN tunneling. A diffusion layer region is formed to a P-type, where read mistake write or a so-called read disturb is suppressed by obtaining a P-type device in which a hot carrier generating efficiency is generally assumed to be lower than that of an N-type device.

However, the memory element of FIG. 29 uses the projection 942 formed on the surface of the silicon semiconductor of the grain boundary part 941. The shape and the size of the projection 942 tend to cause variation depending on the fabrication conditions. The memory elements of “IEEE ELECTRON DEVICE LETTERS” pgs. 272-274, VOL. 27, No. 4, April, 2006 and “IEEE ELECTRON DEVICE LETTERS” p 499-501, VOL. 28, No. 6, June 2007 use an electric field that concentrates at the portion of the projection 942, and thus the device characteristic strongly depends on the shape/size of the projection 942. As a result, the characteristic variation among the memory elements becomes large. This is a large problem that may lower the reliability of the memory, and thus is unsuitable for mass production.

### SUMMARY OF THE INVENTION

In view of solving the above problems, the present invention aims to provide at low cost a semiconductor element suited for mass production having a large memory window and having memory characteristics of high reliability by performing high speed write and erase operations at a relatively low voltage and suppressing rewrite degradation. Furthermore, the present invention aims to provide a semiconductor device equipped with a drive circuit of such semiconductor element such as display device, liquid crystal display device, and receiver.

In order to solve the above problems, the present invention provides a semiconductor element having a first feature of the present invention including a semiconductor layer arranged on an insulating substrate; a first diffusion layer region and a second diffusion layer region having conductivity type of P-type, arranged in the semiconductor layer; a charge accumulating film for covering at least a channel region between the first diffusion layer region and the second diffusion layer region and being injected with charges from the channel region; and a gate electrode positioned on a side opposite to the channel region with the charge accumulating film in between.

The P-type semiconductor element of the present invention having such configuration obtained sufficient memory characteristics, that is, write characteristics, erase characteristics, and a large memory window as hereinafter described with FIGS. 4 and 22, according to the experimental results we conducted for the present invention. The N-type semiconductor element formed on the insulating substrate, however, did not obtain sufficient memory characteristics, that is, write characteristics, erase characteristics, and a large memory window as hereinafter described with FIGS. 3, 20 and 21. The present invention has been invented based on such knowledge.

### BRIEF DESCRIPTION OF THE DRAWINGS

FIG. 1A is a schematic cross-sectional view showing a memory element of a first embodiment of the present invention, and FIG. 1B is a plan view thereof;

FIG. 2 is a view explaining a write method of the memory element of the first embodiment of the present invention;

FIG. 3 is a graph showing a write characteristic of an element that is a reference with respect to the memory element of the first embodiment of the present invention;

FIG. 4 is a graph showing write characteristics of the memory element of the first embodiment of the present invention;

FIG. 5 is a graph showing threshold value shift amount in write and substrate heating temperature dependence of the memory element of the first embodiment of the present invention;

FIG. 6 is a graph showing a channel width dependence of the threshold value shift amount in write of the memory element of the first embodiment of the present invention;

FIG. 7A is a graph showing Id-Vg characteristic in read and Id-Vg characteristic in read with the source and the drain interchanged of the memory element of the first embodiment of the present invention, where FIG. 7A shows a case where the gate voltage is −12 V;

FIG. 7B is a graph showing Id-Vg characteristic in read and Id-Vg characteristic in read with the source and the drain interchanged of the memory element of the first embodiment of the present invention, where FIG. 7B shows a case where the gate voltage is −15 V;

FIG. 7C is a graph showing Id-Vg characteristic in read and Id-Vg characteristic in read with the source and the drain interchanged of the memory element of the first embodiment of the present invention, where the semiconductor element uses a gate insulating film thicker than in FIGS. 7A and 7B;

FIG. 7D is a graph showing Id-Vg characteristic in read and Id-Vg characteristic in read with the source and the drain interchanged of the memory element of the first embodiment of the present invention, where the semiconductor element uses a gate insulating film thicker than in FIG. 7C;

FIGS. 8A and 8B are examples of write characteristics at various channel lengths, channel widths, and drain voltages of the memory element of the first embodiment of the present invention;

FIG. 9 is a view where the channel length, the channel width, and the drain voltage are appropriately taken, showing the write shift amount when write is performed for each case;

FIG. 10A is a view showing a case where the plot of FIG. 9 is performed at the write speed of Vgs=−12 V, −15 V, and −18 V;

FIG. 10B is a view showing a case where the plot of FIG. 9 is performed at the write speed of Vgs=12 V, 15 V, and 18 V, where FIG. 10B is a graph of when the write is 100 milliseconds;

FIG. 10C is a view showing a case where the plot of FIG. 9 is performed at the write speed of Vgs=12 V, 15 V, and 18 V, where FIG. 10C is a graph of when the write is one second;

FIG. 11A is a schematic cross-sectional view showing a memory element of a second embodiment of the present invention, and FIG. 11B is a plan view;

FIG. 12 is a schematic view showing the memory element of the second embodiment of the present invention, and shows a plan view of a configuration different from FIG. 11B;

FIG. 13 is a plan view of a structure in which the current of write state becomes high due to leakage current;

FIG. 14 is a view describing a write method of the memory element of the second embodiment of the present invention;

FIG. 15 is a view describing an erase method of the memory element of the second embodiment of the present invention;

FIG. 16 is a view explaining an experiment for estimating the spread of electrons injected in erase in the memory element according to the second embodiment of the present invention;

FIG. 17A is an example of an Id-Vg curve obtained from the experiment of FIG. 16, where the channel length is 0.45 μm. FIG. 17B is when the channel length is 1.2 μm, and FIG. 17C is when the channel length is 1.7 μm;

FIG. 18 is a view showing the experiment result of FIG. 16;

FIG. 19 is a graph showing an erase time dependence of the threshold value shift amount of the erase operation on the memory element of the second embodiment of the present invention, and an erase time dependence of the threshold value shift amount when erase is performed using FN electron injection;

FIG. 20 is a graph showing erase characteristics (Id-Vg characteristics before erase, after erase of 100 milliseconds, after erase of 1 second, after erase of 10 seconds) of the element that is a reference with respect to the memory element of the second embodiment of the present invention;

FIG. 21 a graph showing erase characteristics (Id-Vg characteristics before erase, after erase of 100 milliseconds, after erase of 1 second, after erase of 10 seconds) of the element that is a reference with respect to the memory element of the first embodiment of the present invention, the erase characteristics being of when erase is performed at a higher voltage than FIG. 20;

FIG. 22 is a graph showing erase characteristics (Id-Vg characteristics before erase, after erase of 1 millisecond, after erase of 10 milliseconds, after erase of 100 milliseconds) of the memory element of the first embodiment of the second invention;

FIG. 23 shows erase characteristics and characteristics after annealing of the element that is a reference on the memory element of the second embodiment of the present invention;

FIG. 24 is a graph showing erase characteristics after write of the memory element of the second embodiment of the present invention;

FIG. 25 is a circuit block diagram of a liquid crystal display device according to a third embodiment of the present invention;

FIG. 26 is a circuit block diagram of a display device according to a fourth embodiment of the present invention;

FIG. 27 is a configuration view of a receiver according to a fifth embodiment of the present invention;

FIG. 28 is a schematic cross-sectional view showing a non-volatile memory of the prior art; and

FIG. 29 is a schematic cross-sectional view showing a non-volatile memory of the prior art.

### DESCRIPTION OF THE PREFERRED EMBODIMENTS

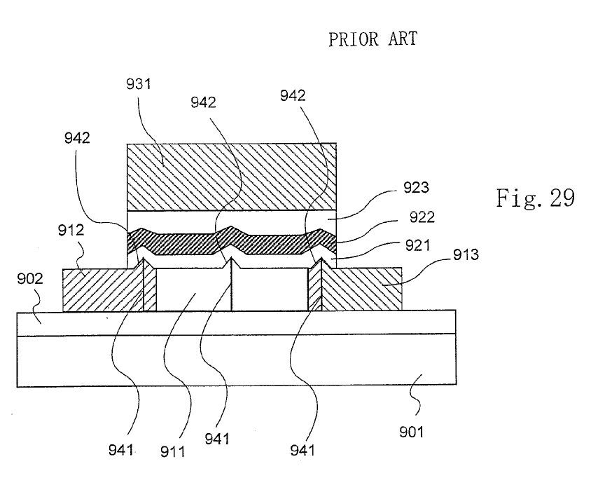

Generally, a non-volatile memory formed on a single crystal semiconductor substrate operates at higher speed and operates at a lower voltage in the N-type device than the P-type device, and thus the N-type device is considered desirable in forming the non-volatile memory. In the case of the non-volatile memory on the single crystal semiconductor substrate, the write is performed by charge injecting hot carriers generated by flowing a channel current to the charge trap insulating film 922. This method enables charge injection of higher speed at a lower voltage than the charge injection using the FN tunneling current and does not require the projections of the semiconductor as in the memory element of FIG. 29. N-type device is generally used. The electron injection is performed in the N-type device, whereas electron hole injection is performed in the P-type device with respect to the charge trap insulating film. However, when using a silicon dioxide film for a bottom insulating film, in particular, the efficiency of charge injection is lower in the P-type device since a barrier with respect to the electron holes is higher than a barrier with respect to the electrons. Furthermore, although the channel current is formed by the electron holes in the P-type device, the ionization rate in the channel is smaller for the electron holes, and the generating efficiency of the hot carriers is low. As the impurities for forming the drain are boron, which is a light element, the steepness of junction at the drain end is gradual in the P-type device, and the hot carrier generating efficiency at the drain end is also low. In view of such aspects, it is assumed that the hot carrier injection efficiency is poorer in the P-type device, and thus use of the N-type device is preferable as write can be performed at a low voltage and at high speed.

Similarly, the N-type device is desirable when forming the memory element on the insulating substrate. This is also the same in “IEEE ELECTRON DEVICE LETTERS” pgs. 272-274, VOL. 27, No. 4, April, 2006, and the like.

According to our experimental results, however, the N-type memory element formed on the insulating substrate made of glass or resin cannot obtain sufficient memory characteristics, that is, write characteristics, erase characteristics, and a large memory window when forming the memory element on the insulating substrate. If the P-type memory element, which originally was thought that memory performance as high as N-type memory element cannot be obtained, is formed on the insulating substrate, sufficient memory characteristics, that is, write characteristics, erase characteristics, and a large window were surprisingly obtained.

When forming the memory element on the single crystal semiconductor substrate, the crystalline of the semiconductor forming the channel region is extremely high, and furthermore, high temperature process can be used in a device forming process such as film forming. For instance, in forming the bottom insulating film, thermal oxidation method of the surface of the semiconductor substrate can be used, and a high density film can be used. Thus, the memory formed on the single crystal silicon substrate is relatively strong to damages from the hot carriers, and the hot carrier injection can be used in memory rewrite.

When forming the memory element on the insulating substrate made of glass or resin, the heat resistance of the substrate is lower than the single crystal semiconductor substrate, and the high temperature process cannot be used in the device forming process. Thus, the crystalline of the semiconductor layer forming the channel region is relatively low, and a film quality of the bottom insulating film cannot use a high density film as when forming the semiconductor element on the single crystal semiconductor substrate. Due to the influences thereof, if hot carrier injection similar to the memory formed on the single crystal semiconductor substrate is performed with respect to the N-type memory element formed on the insulating substrate, the semiconductor element is greatly damaged, and stable memory characteristics cannot be obtained.

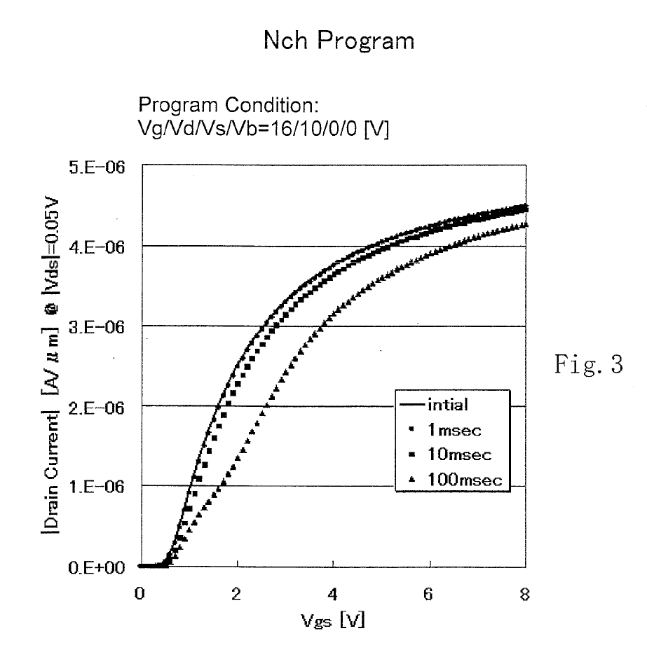

Actually, “SID 05 Digest”, p. 1152-1155, 2005, by Hung-Tse Chen et al., also shows that the characteristics greatly degraded after rewrite of only five times when the write method using hot carriers was used (see “SID 05 Digest”, p. 1152-1155; 2005, by Hung-Tse Chen et al., FIG. 3(c)).

According to our experimental results, it was found that the P-type memory element formed on the insulating substrate exhibits a unique mechanism, whereby sufficient memory characteristics, that is, write characteristics, erase characteristics, and a large memory window, which cannot be obtained with the N-type memory element, can be obtained, and the damage on the semiconductor element is small. The present invention has been invented based on such knowledge.

The semiconductor element of the present invention can be used as a so-called semiconductor memory element for write or erase of data. The semiconductor element of the present invention also can be used as a semiconductor element which threshold value is adjusted by adjusting the write amount and maintaining such write state. Therefore, according to the configuration described above, the charge injection to the charge accumulating film is performed to store information, the high speed write or erase operation can be performed at a relatively low voltage to the P-type semiconductor element, and the rewrite degradation can be suppressed. A semiconductor element having a large memory window and having a high reliability is consequently realized.

In a semiconductor element having a first feature of the present invention, the insulating substrate has a thermal conductivity of between 0.1 and 9 W/m·K. More preferably, the insulating substrate is a glass substrate having a thermal conductivity of between 0.5 and 2 W/m·K. The insulating substrate may be a resin substrate having a thermal conductivity of between 0.1 and 2 W/m·K.

The charges injected to the charge accumulating film by the channel region are charges generated from carrier generation over an entire surface of the channel region subjected to assistance of heat generated by current when the current flows from a first diffusion region to a second diffusion region through the channel region.

The charges injected to the charge accumulating film by the channel region are charges injected so that the charges are distributed substantially symmetric in the charge accumulating film by being subjected to assistance of heat generated by current when the current flows from a first diffusion layer region to a second diffusion layer region through the channel region.

The charges injected to the charge accumulating film by the channel region are charges trapped in the charge accumulating film in the vicinity of at least the first diffusion layer region by being subjected to assistance of heat generated in the channel region by current when the current flows from the first diffusion layer region to the second diffusion layer region through the channel region.

The charges injected to the charge accumulating film by the channel region are injected by being subjected to assistance of heat generated by current when the current flows from the first diffusion layer region to the second diffusion layer region through the channel region, where in a state the charges are injected in the charge accumulating film, a difference between a threshold value of when a reference potential is applied to the first diffusion layer region and a negative voltage is applied to the second diffusion layer region, and a threshold value of when the reference potential is applied to the second diffusion layer region and a negative voltage is applied to the first diffusion layer region is smaller than or equal to 10%.

According to the semiconductor element having each configuration, when performing electron hole injection to a charge accumulating film for information storage, heat is generated by flowing between the diffusion layer regions, and electron hole injection of high efficiency and with less damage to the element using such heat can be realized. A semiconductor element having a wide memory window margin and a high reliability is thereby obtained, and in particular, a wide window margin in which degradation by damage is small even if rewrite of the memory is repeatedly performed is ensured. Such high performance semiconductor element can be obtained through fabrication at low cost using the insulating substrate.

In the semiconductor element having the first feature of the present invention, the upper surface of the semiconductor layer is preferably substantially flat in the channel region. According to the semiconductor element, the manufacturing cost can be suppressed since a complex process such as forming projections on the surface of the semiconductor layer is not necessary, and furthermore, variation in shape among the elements is small and the characteristic variation among the elements can be suppressed since the upper surface of the channel is substantially flat and has a smooth shape. Therefore, a semiconductor element suited for mass production can be obtained.

In the semiconductor element having the first feature of the present invention, the semiconductor layer is preferably formed to an island form on the insulating substrate. An inter-layer insulating film is preferably formed on the semiconductor layer and the gate electrode. At least one part of the inter-layer insulating film preferably consists of resin. The film thickness of the semiconductor layer is preferably between 30 nm and 150 nm. The channel width of the channel region is preferably between 0.5 μm and 100 μm. The channel width of the channel region is preferably between 2 μm and 20 μm. The channel length of the channel region is preferably between 0.1 μm and 3.4 μm. The channel length of the channel region is preferably between 0.1 μm and 2.4 μm. The channel length of the channel region is preferably between 0.1 μm and 0.9 μm. The charge accumulating film preferably has a stacked structure including at least a first insulating film, a charge accumulating film having a charge accumulating ability, and a second insulating film. In particular, the charge accumulating film having the charge accumulating ability is preferably a nitride film or a high dielectric film.

According the semiconductor element having such features, a suitably operating semiconductor element is obtained as the semiconductor element of the present invention.

In the semiconductor element having the first feature of the present invention, the semiconductor layer further includes a contact region having a conductivity type of N-type, and the contact region contacts a control terminal. Furthermore, a semiconductor layer region of lower concentration than an impurities concentration of the contact region is formed between the contact region, and the first diffusion layer region and the second diffusion layer region. The gate electrode is arranged on the semiconductor layer region of low concentration.

According to such semiconductor element, when the control terminal and the body contact region having a conductivity type of N-type contact, the controllability of the body potential can be enhanced and the operation variation can be suppressed since the contact resistance between the control terminal and the body contact region is low and an ohmic connection can be adopted.

Since the low concentration region is arranged between the contact region and the diffusion layer regions, and the gate electrode is arranged on the low concentration region, in particular, the junction leakage flowing between the contact region and the diffusion layer region can be suppressed as much as possible when reverse voltage is applied thereto.

A semiconductor device having a second feature of the present invention further includes a display device on the insulating substrate.

According to such configuration, since the semiconductor element of the present invention is formed on the panel substrate of the display device, the cost of the outside part itself, and the attachment cost of the outside part can be reduced. The examination cost can also be reduced since the automation of adjustment is facilitated. Furthermore, the semiconductor element of the present invention is advantageous in reducing the cost since the structure of the gate insulating film is simple and the necessary number of processes is small.

A semiconductor device having a third feature of the present invention is a liquid crystal display device including a liquid crystal display device including, scanning lines and signal lines arranged in a matrix form, a drive circuit for selectively driving a pixel electrode corresponding to one pixel, the one pixel being a region surrounded by the scanning line and the signal line, and a liquid crystal interposed between the pixel electrode and an opposite electrode facing thereto; and a liquid crystal drive circuit, including, a voltage output circuit, input with digital information, for outputting a voltage defined by the digital information to the opposite electrode, a DA converter for converting digital tone data to an analog tone signal, and a storage circuit including a semiconductor element for storing data defining a correlation between the digital tone data and a voltage of the analog tone signal, the semiconductor element being the semiconductor element according to claim 1, on a panel substrate.

According to the liquid crystal display device having the above configuration, since the semiconductor element having the first feature of the present invention is formed on the panel substrate of the liquid crystal display device, the cost of the outside part itself, and the attachment cost of the outside part can be reduced. The examination cost can also be reduced since the automation of adjustment is facilitated. Furthermore, the semiconductor storage device of the present invention is advantageous in reducing the cost since the structure of the gate insulating film is simple and the necessary number of processes is small.

A semiconductor device having a fourth feature of the present invention is a receiver including a display device; a receiving circuit for receiving an image signal; an image signal circuit for providing the image signal received by the receiving circuit to the display device; and a storage circuit including a semiconductor element for storing data necessary for generating the image signal, the semiconductor element being the semiconductor element according to claim 1.

According to the receiver having the above configuration, high function receiver can be realized at low cost since the display device formed with the semiconductor storage device having the first feature of the present invention is arranged.

A semiconductor element having a fifth feature of the present invention further includes a heating means for heating the insulating substrate.

According to the semiconductor element having the above configuration, the electron hole injection is promoted by heating the insulating substrate, and the electron holes can be injected at high speed while suppressing element degradation by injection damage.

A semiconductor device having a sixth feature of the present invention includes a semiconductor element with a semiconductor layer arranged on an insulating substrate, first diffusion layer region and a second diffusion layer region having a conductivity type of P-type arranged in the semiconductor layer, a charge accumulating film for covering at least a channel region between the first diffusion layer region and the second diffusion layer region of the semiconductor layer and being injected with charges from the channel region, and a gate electrode positioned on a side opposite to the channel region with the charge accumulating film in between; a first voltage application circuit connected to the first diffusion layer region of the semiconductor element by way of a first switching element; a second voltage application circuit connected to the second diffusion layer region of the semiconductor element by way of a second switching element; and a third voltage application circuit connected to the gate electrode of the semiconductor element by way of a third switching element.

Therefore, according to the semiconductor device having such configuration, a semiconductor device which performs charge injection to the charge accumulating film for information storage, and which performs high speed write or erase operation at a relatively low voltage to the P-type semiconductor element is provided, and furthermore, the write degradation can be suppressed. As a result, a semiconductor element having a large memory window and a high reliability can be driven.

In the semiconductor device having the sixth feature of the present invention, the second voltage application circuit and the third voltage application circuit preferably output voltages lower than a voltage output by the first voltage application circuit.

According to the semiconductor device having the above configuration, heat is generated by flowing current between the diffusion layer regions, and electron hole injection of high efficiency and reduced damage on the element using such heat is realized. Through such operation, information can be stored by injecting electron holes to the charge accumulating film. A semiconductor element having a wide memory window margin and a high reliability is thereby obtained, and a wide memory window margin with reduced degradation by damage even if rewrite of memory is repeatedly performed in particular is ensured. Such high performance semiconductor device is obtained through fabrication at low cost using the insulating substrate.

In the semiconductor device having the sixth feature of the present invention, the third voltage application circuit outputs a voltage lower than a voltage output by the second voltage application circuit.

According to the semiconductor device having the above configuration, the horizontal electric field at the ends of the diffusion layer regions can be alleviated by the electric field of the gate electrode, and thus hot carrier generating efficiency by impact ionization at the ends of the diffusion layer regions becomes low, and the damage on the gate insulating film, and the boundary of the gate insulating film and the body region is reduced.

A semiconductor device having a seventh feature of the present invention includes a semiconductor element with a semiconductor layer arranged on an insulating substrate, a first diffusion layer region and a second diffusion layer region having a conductivity type of P-type arranged in the semiconductor layer, a body region including at least a channel region between the first diffusion layer region and the second diffusion layer region of the semiconductor layer, a charge accumulating film for covering the channel region and being injected with charges from the channel region, and a gate electrode positioned on a side opposite to the channel region with the charge accumulating film in between; a first voltage application circuit connected to the first diffusion layer region of the semiconductor element by way of a first switching element; a second voltage application circuit connected to the second diffusion layer region of the semiconductor element by way of a second switching element; a third voltage application circuit connected to the gate electrode of the semiconductor element by way of a third switching element; and a fourth voltage application circuit connected to the body region by way of a fourth switching element.

According to the semiconductor device having such configuration, charge injection to the charge accumulating film is performed for information storage, high speed write or erase operation can be performed at a relatively low voltage to the P-type semiconductor element, and rewrite degradation can be suppressed. As a result, a semiconductor device having a large memory window and a high reliability can be realized. The semiconductor device of the present invention can realize a semiconductor device adjusted with a threshold value by adjusting the write amount and maintaining the write state. Furthermore, high speed erase operation can be realized at a relatively low voltage by controlling the body potential. Since erase is performed by electron injection, the gate insulating film and the boundary thereof are less likely to be damaged, and the degradation of the device performance is small.

In the semiconductor device having the seventh feature, the third voltage application circuit and the fourth voltage application circuit desirably output voltages higher than a voltage output by the first voltage application circuit.

According to the semiconductor device having such configuration, one part of the carriers generated in erase are also discharged from the body contact, whereby the controllability of the body potential enhances and the operation variation among devices is reduced.

In the semiconductor device having the seventh feature of the present invention, the second voltage application circuit desirably outputs substantially the same voltage as a voltage output by the first voltage application circuit.

According to the semiconductor device having such configuration, the high energy carriers are generated, one part of electrons are drawn to the potential of the gate electrode and injected to the gate insulating film, and erase is performed.

In the semiconductor device having the seventh feature of the present invention, the third voltage application circuit desirably outputs a voltage higher than a voltage output by the fourth voltage application circuit.

According to the semiconductor device having such configuration, erase of higher speed can be realized.

The semiconductor element device having the seventh feature of the present invention includes a decoder circuit for selectively controlling the switching element. The timing of voltage application, the voltage application time, and the voltage application order then can be appropriately controlled.

Another aspect of the present invention relates to a driving method of a semiconductor element having an eighth feature of, using a semiconductor layer arranged on an insulating substrate, first diffusion layer region and a second diffusion layer region having a conductivity type of P-type arranged in the semiconductor layer, a body region including at least a channel region between the first diffusion layer region and the second diffusion layer region of the semiconductor layer, a charge accumulating film for covering the channel region and being injected with charges from the channel region, and a gate electrode positioned on a side opposite to the body region with the charge accumulating film in between, applying a negative voltage to the second diffusion layer region and the gate electrode with respect to a reference voltage applied to the first diffusion layer region, generating a current in the channel region and generating heat, and injecting electron holes to the charge accumulating film, as an operation related to information storage.

According to such driving method, the electron holes are injected to the gate insulating film from the entire surface of the channel region to perform write. Sufficient write characteristics, erase characteristics, and a large memory window can be obtained by performing write in such manner.

As the operation related to information storage, in the driving method of the semiconductor element of the present invention, the negative voltage applied to the gate electrode desirably has a larger absolute value than the negative voltage applied to the second diffusion layer region in the embodiment.

The generated electrons then can be effectively pulled by the electric field of the gate electrode, and speed of the write can be increased.

As the operation related to information storage, in the driving method of the semiconductor element of the present invention, in the embodiment, the electrons are desirably injected to the charge accumulating film by applying a positive voltage to the gate electrode and the body region with respect to the reference voltage applied to the first diffusion layer region.

High energy carriers are thereby generated, and some carriers are pulled and injected to the gate insulating film thereby performing erase.

As the operation related to information storage, in the driving method of the semiconductor element of the present invention, a positive voltage is desirably applied to the gate electrode and the body region with a potential of the P-type second diffusion layer region at substantially the same potential with respect to the reference voltage applied to the P-type first diffusion layer region. High energy carriers are thereby generated, and some carriers are pulled and injected to the gate insulating film thereby performing erase.

In the driving method of the semiconductor element of the present invention, a positive voltage applied to the gate electrode is desirably higher than a positive voltage applied to the body region in the operation of injecting electrons to the charge accumulating film. Erase of higher speed then can be performed.

In the driving method of the semiconductor clement of the present invention, the negative voltage applied to the second diffusion layer region is desirably between −6 V and −14 V, and the negative voltage applied to the gate electrode is desirably a voltage having a large absolute value. In particular, the negative voltage applied to the gate electrode is preferably between −6 V and −18 V.

The electron holes having sufficient energy to inject the electron holes to the gate insulating film from the entire surface of the channel region are thereby generated, and write is performed.

In the driving method of the semiconductor element of the present invention, the positive voltage applied to the body region is desirably between 6 and 15 V, and the positive voltage applied to the gate electrode is desirably a higher voltage. In particular, the positive voltage applied to the gate electrode is preferably between 6 V and 30 V.

High energy carriers are thereby generated, and some carriers are pulled and injected to the gate insulating film thereby performing erase.

A semiconductor device having a ninth feature of the present invention further includes a display device on the insulating substrate.

According to such configuration, since the semiconductor element of the present invention is formed on the panel substrate of the display device, the cost of the outside part itself, and the attachment cost of the outside part can be reduced. The examination cost can also be reduced since the automation of adjustment is facilitated. Furthermore, the semiconductor element of the present invention is advantageous in reducing the cost since the structure of the gate insulating film is simple and the necessary number of processes is small.

A semiconductor element having a tenth feature of the present invention is a liquid crystal display device including a liquid crystal display device in which scanning lines and signal lines are arranged in a matrix form, a drive circuit for selectively driving a pixel electrode corresponding to one pixel, the one pixel being a region surrounded by the scanning lines and the signal lines, is arranged, and a liquid crystal is interposed between the pixel electrode and an opposite electrode opposing thereto; a voltage output circuit, input with digital information, for outputting a voltage defined by the digital information to the opposite electrode, a DA converter for converting digital tone data to an analog tone signal, and a semiconductor device for storing data defining a correlation between the digital tone data and a voltage of the analog tone signal on a panel substrate of the liquid crystal display device.

According to such configuration, since the semiconductor device having the sixth or the seventh feature of the present invention is formed on the panel substrate of the liquid crystal display device, the cost of the outside part itself, and the attachment cost of the outside part can be reduced. The examination cost can also be reduced since the automation of adjustment is facilitated. Furthermore, the semiconductor storage device of the present invention is advantageous in reducing the cost since the structure of the gate insulating film is simple and the necessary number of processes is small.

A semiconductor device having an eleventh feature of the present invention is a receiver, the receiver including a display device; a receiving circuit for receiving an image signal; an image signal circuit for providing the image signal received by the receiving circuit to the display device; and the semiconductor device for storing data necessary for generating the image signal on the panel substrate of the display device.

According to such configuration, high function receiver can be realized at low cost since the display device formed with the semiconductor device having the sixth or the seventh feature of the present invention is arranged.

A semiconductor device having a twelfth feature of the present invention further includes a heating means for heating the insulating substrate.

According to such configuration, the electron hole injection is promoted by heating the insulating substrate, and the electron holes can be injected at high speed while suppressing element degradation by injection damage.

As described above, according to the semiconductor element having the first feature of the present invention, two information storing state of small read current/large read current are respectively brought on by electron hole injection/electron injection. The former electron hole injection uses the effect of causing the element to generate heat by flowing current and promoting the electron hole injection by such heat, and thus has an effect in that the damage degradation is small, and even if damage occurs at one part, such damage can be recovered with the annealing effect by heat. The electron injection of reduced damage leads to information storing state of large read current, and thus a large window margin, which is the difference between the information storing states, can be obtained, and in particular, a semiconductor memory element with reduced degradation and high reliability even if rewrite is repeatedly performed is obtained.

According to the semiconductor element having the second feature of the present invention, since the semiconductor element of the present invention is formed on the panel substrate of the display device, the cost of the outside part itself, and the attachment cost of the outside part can be reduced. The examination cost can also be reduced since the automation of adjustment is facilitated. Furthermore, the semiconductor element of the present invention is advantageous in reducing the cost since the structure of the gate insulating film is simple and the necessary number of processes is small.

According to the semiconductor device having the third feature of the present invention, since the semiconductor element of the present invention is formed on the panel substrate of the liquid crystal display device, the cost of the outside part itself, and the attachment cost of the outside part can be reduced. The examination cost can also be reduced since the automation of adjustment is facilitated. Furthermore, the semiconductor element of the present invention is advantageous in reducing the cost since the structure of the gate insulating film is simple and the necessary number of processes is small.

According to such configuration, high function receiver can be realized at low cost since the display device formed with the semiconductor element of the present invention is arranged.

According to the semiconductor element having the fifth feature of the present invention, electron hole injection of higher speed or at a lower voltage is realized.

### First Embodiment

Two states, that is, a write state and an erase state related to information storage are defined as below in the following description.

The write state is defined mainly as when a majority carriers of carriers in a conductivity type of first and second diffusion layer regions are accumulated in a gate insulating film having a function of accumulating charges. The erase state is defined as when the carriers of the opposite type are mainly accumulated or when the accumulated charges are effectively scarce. The erase state includes a case where the electron holes and the electrons are both accumulated and thus cancel out the respective potentials, so that the accumulated charges are effectively scarce.

A semiconductor element according to the present invention is a P-channel semiconductor element in which the first and second diffusion layer regions are P-type. In this case, a state in which the electron holes are mainly accumulated in the gate insulating film having a function of accumulating charges is defined as the write state, and a state in which the electrons are mainly accumulated or when the accumulated charges are effectively scarce is defined as the erase state.

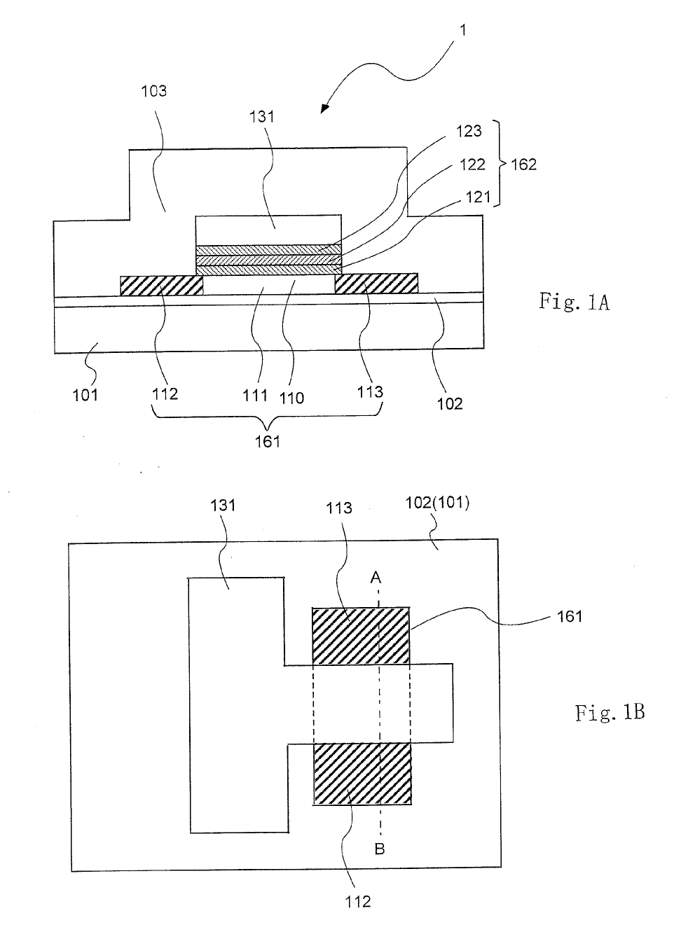

A first embodiment of the present invention will be described using FIG. 1. FIG. 1A is a cross-sectional frame format view taken along line A-B of FIG. 1B, and FIG. 1B is a plan frame format view. In a semiconductor element (hereinafter also referred to as memory element) 1 of the first embodiment, a base insulating film 102 is formed on an insulating substrate 101 including glass substrate or resin substrate, and a semiconductor layer 161 is further formed on the base insulating film 102. Two diffusion layer regions 112 and 113 having a conductivity-type of P-type are formed in the semiconductor layer 161 so as to sandwich at least one part of a body region 111. The diffusion layer regions function as a source region and a drain region.

The body region 111 has a conductivity-type of N-type or is intrinsic. A channel region 110 forms in the surface layer of the semiconductor layer 161 when the source region and the drain region function. The upper surface of the semiconductor layer formed with the channel region 110 is flat. Flat, herein, means that concavity and convexity are not intentionally formed when fabricating the semiconductor layer 161. Therefore, in the present invention, if the upper surface of the semiconductor layer is flat, this refers to the flatness of an extent obtained by the fabrication of a normal semiconductor layer. For instance, it refers to surface flatness of an amorphous semiconductor layer when forming the semiconductor layer through vapor deposition method. Furthermore, it refers to the flatness such as obtained when forming a CG silicon in forming the amorphous semiconductor layer through laser annealing. A state in which the concavity and convexity of the semiconductor layer are smaller than the film thickness of the semiconductor layer is preferable, and the size of the concavity and convexity is preferably smaller than or equal to 10 nm. The present invention is referring to such flatness. The semiconductor layer intentionally formed with concavity and convexity is not desirable as it lowers mass productivity, and becomes the cause of characteristic variation among elements.

The semiconductor layer 161 is formed to an island form of a size capable of forming the memory element. FIG. 1 shows an example where the semiconductor layer 161 is separated for every memory element, but in some cases, one or both of the diffusion layer regions 112, 113 may be shared with an adjacent memory element. The memory element and at least one part of a peripheral circuit TFT may be included in one island semiconductor layer 161.

A gate insulating film 162 having a function of accumulating charges is stacked on the semiconductor layer 161, and a gate electrode 131 is stacked thereon. The vicinity of the boundary with the gate insulating film 162 of the body region 111 is a region where an inversion layer forms when a transistor is turned ON, and is the so-called channel region 110. The semiconductor storage device of the first embodiment of the present invention is configured to change the current flowing between the two diffusion layer regions by the magnitude of the charges accumulated in the gate insulating film. Specifically, the storage state can be read out by the magnitude of the current amount, where the current amount is small in the write state and the current amount is large in the erase state.

An inter-layer insulating layer 103 is formed on the upper part of the memory element having the above structure so as to cover the entire memory element and the substrate.

The insulating substrate 101 includes glass substrate or resin substrate, but transparent glass substrate or transparent resin substrate is preferably used so that the substrate can also be used as a display of a transmissive liquid crystal panel and the like if it is transparent. Use of the resin substrate is preferable since the substrate can be easily made flexible, lighter, and can have higher impact resistance. The thickness of the insulating substrate 101 is normally about 1 mm in the case of the glass substrate. After forming the semiconductor element of the present invention on the glass substrate through the semiconductor process, the back surface of the substrate is preferably grinded to about several hundred μm to make the display device lighter and thinner. Similarly in the case of the resin substrate, the back surface of the substrate is preferably grinded to about several hundred μm after forming the semiconductor element of the present invention on the substrate.

In particular, if heat insulation performance of the insulating substrate 101 is satisfactory, the temperature of the semiconductor element can be effectively raised by the heat generated in the semiconductor element during write, and the write speed can be increased by the effect of heat, as hereinafter described. Therefore, since the substrate having the insulating layer formed on a silicon substrate such as SOI substrate has satisfactory heat radiation performance, such substrate is not suited for the substrate used in the semiconductor element of the present invention.

Considering a semiconductor element on a general silicon substrate, the thermal conductivity of a crystalline silicon or a substrate takes, although it depends on the crystal condition, a relatively high thermal conductivity value of about 160 W/m·K as a typical value. Thus, even if heat is generated when current is flowed to the semiconductor element, such heat is rapidly diffused into the semiconductor substrate.

If a material of high heat insulation performance is used for the substrate 101 as in the first embodiment, the heat generated in the semiconductor element is less likely to diffuse into the substrate on the lower side. Current is flowed to the semiconductor element during the write operation, as hereinafter described, but Joule heat generated in this case is less likely to diffuse to the lower side due to the heat insulation performance of the substrate 101, whereby the temperature of the semiconductor element effectively rises. Therefore, the insulating substrate 101 used in the present invention preferably has high as possible heat insulation performance, and a thermal conductivity lower than the silicon substrate. In reality, however, the glass substrate and the resin substrate can be used as the insulating substrate having better heat insulation performance than the silicon substrate.

The memory element of the first embodiment has, as its main feature, a property in that the write efficiency enhances when the device temperature is high, that is, high write efficiency is brought on by the highness of the heat insulation performance of the insulating substrate 101.

For instance, if a quartz substrate is used as the insulting substrate 101, the thermal conductivity value is between 8 and 9 W/m·K, which is lower than the semiconductor substrate.

If the glass substrate is used, the substrate has a lower thermal conductivity value, or has a thermal conductivity value of smaller than or equal to 2 W/m·K, or between about 0.5 and 1.5 W/m·K as a typical value, and thus high heat insulation performance can be provided to the substrate 101.

With regards to the resin substrate, resin such as polycarbonate resin, polysulfone resin, polymethylpentene resin, polyarylate resin, polyimide resin, phenol resin, and the like have a relatively high heat resistance, and can be more effectively used. Although it depends on the material and the density, the thermal conductivity of such resin is smaller than or equal to 2 W/m·K, and resin having a value of about 0.1 to 0.2 W/m·K for the lower ones is provided in the market and thermal conductivity lower than that of the glass substrate can be obtained. Thus, the heat generated in the semiconductor element is less likely to escape, and high write efficiency can be obtained.

The thermal conductivity can be measured through a laser flash method. The laser flash method is known from Japanese Laid-Open Patent Publication No. 2003-065982 and the like.

The diffusion of heat generated in the semiconductor element is suppressed the lower the thermal conductivity of the substrate, which leads to high write efficiency, but an appropriate material is selected according to each solid-state property of the substrate material, specification and application of the semiconductor element to be formed, and the like. For instance, if the glass substrate is used, the substrate can be used as the display of the transmissive liquid crystal panel and the like as it is transparent, as described above, and the memory element of the first embodiment can be formed on the same substrate as the display. Since the glass substrate has a very low thermal conductivity, high write efficiency is obtained, and the semiconductor element can be fabricated at a lower cost than when the semiconductor substrate is used. If the resin substrate is used, the thermal conductivity is generally lower than the glass substrate, and has stronger resistance to impact than the glass substrate. In particular, since polycarbonate resin or polyarylate resin is used, application can be made to displays as such resin excels in light transmissivity.

Therefore, the substrate having low thermal conductivity effectively exhibits promotion of write efficiency by heat during the write. The heat assistance effect will again be described in detail hereinafter.

The base insulating film 102 is not necessarily required. However, if the glass substrate is used for the insulating substrate 101, silicon dioxide film, silicon oxynitride film, silicon nitride film, or a stacked film thereof is preferably used as the base insulating film 102. In this case, the base insulating film 102 acts as a barrier and prevents the semiconductor element formed on the glass substrate from being contaminated by impurities diffused from the glass substrate. Generally, the thermal conductivity of the silicon nitride film is higher than the thermal conductivity of the glass although it depends on the structure, and thus if silicon nitride film is used for one part of the base insulating film, the film thickness is preferably less than or equal to 1 μm, whereby the heat insulation performance of the substrate is not greatly damaged. Furthermore, it is particularly effective to use a film of low thermal conductivity such as silicon dioxide film at least for the uppermost layer of the base insulating film.

The semiconductor layer 161 may use amorphous, polycrystalline, or single crystal silicon. The effects of the present invention are significantly obtained by preferably using the CG (Continuous Grain) silicon in which the amorphous silicon is laser annealed to increase the crystal grain boundary so as to approach the characteristics of the single crystal.

The semiconductor element of the first embodiment is formed using a relatively low temperature process, where the crystal condition of the semiconductor layer and the boundary state of the semiconductor layer and the gate insulting film are not satisfactory compared to when an element is formed on the single crystal substrate using a high temperature process. Thus, an element obtained has a relatively low mobility in the channel, and a high channel resistance of a certain extent. In the element of the first embodiment, the carrier mobility in the channel in the initial state, that is in an electrically neutral state in which the write operation nor the erase operation is performed even once after the element is fabricated takes a value of between about 60 and 120 cm²/V·s in the measurement under normal temperature in a linear region. If the mobility is too low and the channel resistance is too high, the current amount in write becomes small and Joule heat becomes hard to generate, and thus the carrier mobility is preferably greater than or equal to 30 cm²/V·s. In this regards, polycrystal or single crystal is more suited for the structure of the semiconductor layer than amorphous.

Other than the above semiconductors, a semiconductor material such as silicon germanium, germanium and the like can be used. The film thickness of the semiconductor layer 161 is preferably between 30 nm and 150 nm. The evenness of film thickness becomes difficult to maintain if less than 30 nm, and the semiconductor layer under the channel may not be completely depleted during the transistor operation if greater than 150 nm, which may degrade the properties. However, since complete depletion is unnecessary in the operation of the memory element of the present invention, the film thickness may be greater than or equal to 150 nm or a few μm when forming only the memory element on the semiconductor layer 161.

In the first embodiment, the element is a P-channel type since two diffusion layer regions 112, 113 have a conductivity-type of P-type. The present invention obtains a large memory window and excels in holding characteristic since the speed of the write and erase operations is increased by having the clement of a P-channel type as hereinafter described. The body region 111 preferably has a conductivity-type of N-type or is intrinsic.

The gate insulating film 162 formed on the channel region 110 of the semiconductor layer 161 has a function of accumulating charges. The thickness is preferably between 20 nm and 150 nm. If the thickness is smaller than 20 nm, uniformity of the film thickness becomes difficult to maintain and pressure resistance becomes insufficient. If the thickness is greater than or equal to 150 nm, the threshold value becomes very high, and the on-current becomes significantly small.

More specifically, the gate insulating film 162 has a structure in which a silicon nitride film 122 serving as a charge accumulating insulating film is sandwiched between a bottom insulating film 121 and a top insulating film 123 respectively composed of silicon dioxide film.

If the gate insulating film 162 has a three-layer structure including the silicon nitride film 122 serving as the charge accumulating insulating film, the charges held in the silicon nitride film 122 are inhibited from flowing outside by the bottom insulating film 121 and the top insulating film 123, and thus the charge holding property enhances.

In particular, if the glass substrate or the resin substrate is used for the insulating substrate 101, the heat resistance becomes lower than the semiconductor substrate, and high temperature process as when the semiconductor substrate is used cannot be used in fabricating the semiconductor element. Thus, in the film formation of the bottom insulating film 121, high density film cannot be formed as much as when forming the semiconductor element on the semiconductor substrate. Thus, defects are likely to occur compared to the high density film. Such defects have a possibility of becoming a leakage path for the held charges.

In a so-called floating gate structure including a conductor such as polysilicon in place of the charge accumulating insulating film 122 for the charge accumulating region to store information, the charges are accumulated in the conductor. Thus, when the leakage path of the charges form at least at one location of the bottom insulating film, the held charges sequentially flow out, and information can no longer be stored. The bottom insulating film thus needs to be formed so that the leakage path does not form.

In this regards, the charge accumulating insulating film 122 such as silicon nitride film is preferably used for the charge accumulating region as in the first embodiment. The movement of the held charges in the film is prevented by trapping and holding the charges in the insulating film, where even if one part of the bottom insulating film 121 is defected thereby forming a leakage path of the charges, only the charges near the defect flow out and most of the charges remain in the charge accumulating insulating film. A memory element of high reliability with strong resistance to defect is obtained.

In the first embodiment, a preferred film thickness example is to have the bottom insulating film 121 to between 5 nm and 20 nm, the silicon nitride film 122 to between 10 nm and 50 nm, and the top insulating film 123 to between 5 nm and 50 nm. The effect of preventing the flow of the charges out from the charge holding film lowers and the holding time becomes short if the bottom insulating film 121 and the top insulating film 123 are thinner than 5 nm. If the gate insulating film 162 including such films is thick, the effect of the gate electric field on the channel becomes weak, and the write speed becomes slow. In particular, with regards to the bottom insulating film 121, the charge injection efficiency lowers if the film thickness is thick since the carriers are injected through the bottom insulating film 121. In addition, since the distance between the silicon nitride film 122 or the charge accumulating film and the channel 110 becomes large, the influence of the accumulated charges on the channel 110 becomes relatively small, thereby lowering the memory window. That is, the window margin narrows if the gate insulating film 162, in particular, the bottom insulating film 121 is too thick. The film thickness described above is thus preferable.

More preferred film thickness is to have the bottom insulating film 121 to between 5 nm and 20 nm, the silicon nitride film 122 to between 10 nm and 30 nm, and the top insulating film 123 to between 5 and 20 nm. In the write operation to be hereinafter described, the gate electric field can be strongly acted on the channel region, and in particular, the horizontal electric field at the drain end can be alleviated by thinning each film thickness and further thinning the gate insulating film 162. The generation of carriers of high enough energy that may damage the semiconductor element is suppressed as much as possible during write by drain avalanche, and the like. The reliability of the memory element is thus high.

With regards to the charge accumulating film, a high dielectric film such as hafnium oxide and zirconium oxide or a film containing conductive particles or nitride particles in the silicon dioxide film may also be used in place of the silicon nitride film 122. The gate insulating film 162 may be a single film of silicon nitride film, or a double layer of silicon dioxide film and silicon nitride film, but is preferably a stacked layer of three or more layers as described above to prevent flow-out of charges from the silicon nitride film and hold the charges for a long period of time.

The gate electrode 131 is formed on the gate insulating film 162. The material of the gate electrode 131 may be metal such as W, Ta, Al, TaN, and TaAlN, or a semiconductor such as amorphous silicon and polysilicon, but is not limited thereto.

The inter-layer insulating film 103 uses a silicon dioxide film, or a stacked film of the silicon dioxide film and the silicon nitride film as representative examples, but other insulating films may be used. The insulating film 103 serves as a heat insulating material for suppressing diffusion of heat generated in the semiconductor element, and contributes to heat assistance to be hereinafter described. It is particularly preferable to have one part of the inter-layer insulating film made of a resin material having low thermal conductivity so that the heat insulation performance is enhanced, which can also be easily realized. The illustration of the inter-layer insulating film 103 is omitted in FIG. 1B.

The memory element of the first embodiment of the present invention can be formed according to the procedures of forming a normal thin-film transistor (TFT). In other words, the silicon semiconductor layer 161, the bottom insulating film 121, the silicon nitride film 122, and the top insulating film 123 may be formed through plasma CVD method.

The impurities that provide the conductivity-type of P-type are introduced into regions to become the two diffusion layer regions 112 and 113 through ion injection method or solid-phase diffusion method. Thereafter, annealing treatment is appropriately performed to form the diffusion layer regions 112, 113. The impurities that provide the conductivity-type of P-type may be boron, aluminum, and the like, where boron is used in the present invention. If boron is used, the impurity concentration is desirably between 1×10^{19 cm}⁻³ and 3×10²⁰ cm⁻³.

A contact and an upper layer metal wiring (not shown) are then arranged to obtain the memory element of the first embodiment.

In the present invention, a complex process of forming the projection 942 on the surface of the semiconductor layer 161 as in FIG. 29 is not necessary.

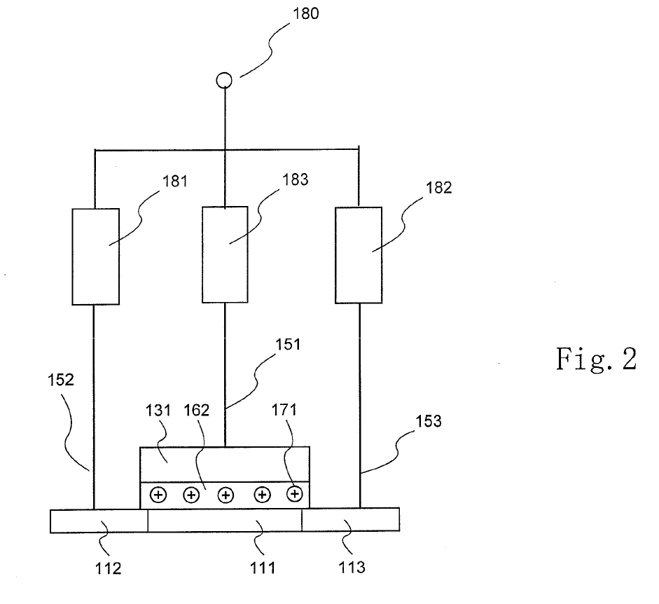

The write method will now be described as an operation method related to information storage of the memory element according to the first embodiment of the present invention. As shown in FIG. 2, a first reference voltage is applied via a first voltage application circuit 181 from a DC power supply 180 to a terminal 152 connected to one P-type diffusion layer region 112. A write voltage negative with respect to the reference voltage (e.g., −6 V to −14 V with respect to reference voltage) is applied via a second voltage application circuit 182 from the DC power supply 180 to a terminal 153 connected to the other P-type diffusion layer region 113. A voltage negative with respect to the reference voltage (e.g., −6 V to −18 V with respect to reference voltage) is applied via a third voltage application circuit 183 from the DC power supply 180 to a terminal 151 connected to the gate electrode 131.

The first voltage application circuit 181, the second voltage application circuit 182, and the third voltage application circuit 183 are respectively configured including a switching element, which switching element is selectively controlled with the timing of voltage application, the voltage application time and the order of voltage application by a decoder circuit (not shown).

The current generates in the channel region between the diffusion layer regions 112 and 113, and Joule heat generates since the channel region is one type of resistor body. Such heat has an effect of generating electron holes having sufficient energy to be injected to the gate insulating film 162 or the charge accumulating film. The write is carried out when the electron holes are injected to the gate insulating film 162 (electron hole 171).

In this case, the channel is not pinched off. The Joule heat is generated regardless of whether the channel is pinched off or not pinched off, as described above. Since the electron holes having sufficient energy are generated at the entire portion of the channel by such heat, the electron holes 171 are injected to the entire region of the gate insulating film 162 positioned on the upper side of the channel region.

The preferred voltage application method is to have a higher absolute value for the negative voltage applied to the gate electrode 131 than the negative voltage applied to the other diffusion layer region 113. If write is carried out under such conditions, the horizontal electric field at the end of the diffusion layer region 113 is alleviated by the electric field of the gate electrode 131, and the hot carrier efficiency by impact ionization etc. lowers near the end of the diffusion layer region 113. Therefore, the possibility of damaging the gate insulating film 162 and the boundary of the gate insulating film 162 and the body region 111 lowers.

Through the use of the above method of applying higher negative voltage to the gate electrode 131, the horizontal electric field at the end of the diffusion layer region 113 can be alleviated and hot carrier generation can be suppressed, and thus has an effect of suppressing the damage. During write of the memory element of the first embodiment, the electron hole injection at the entire body region 111 between the diffusion layer regions 112 and 113 is mainly used, and thus write can be sufficiently carried out even if impact ionization at the end of the diffusion layer region 113 is suppressed. Furthermore, the memory element of high reliability is obtained since the damage by the injection method is small. The merits thereof will be hereinafter described in detail.

The read operation causes transistor operation with the diffusion layer region 113 as the source and the diffusion layer region 112 as the drain. If read is carried out with the write performed, the read current flowing between the diffusion layer region 112 and the diffusion layer region 113 reduces compared to when the write is not performed. Therefore, the write state can be read by the magnitude of the read current.

The reference voltage in write may be matched with the ground potential, or the potential other than the ground potential may be used as necessary. For instance, each voltage example of when the reference voltage is 14 V is, between 8 V and 0 V for the other diffusion layer region 113, and between 8 V and −4 V for the gate electrode 131. In this case, the absolute value of the voltage applied to each terminal can be suppressed, and the peripheral circuit for supplying the voltage can be simplified.

The first embodiment has a feature of being formed as a so-called P-channel semiconductor element, which feature is extremely important in ensuring the memory window. This aspect will be described below.

FIG. 3 is a view showing the write characteristics of the N-channel semiconductor element having a structure similar to the memory element of the present invention. When referring to having a similar structure, this means that the gate length, the gate width, as well as the material, the film configuration, and each film thickness of the gate insulating film are the same as the P-channel semiconductor element. Furthermore, in the formation process, the film forming process, the etching process, the heat process, and the like are also common other than that the ion injection process for forming the diffusion layer region etc. is different to form the N-channel element.

The semiconductor element used in the measurement of FIG. 3 has a configuration shown in the cross-sectional view of FIG. 1A and the plan view of FIG. 1B. The semiconductor element includes the insulating substrate 101 consisting of glass substrate having a thermal conductivity of 1 W/m·K, the CG silicon semiconductor layer 161 having a film thickness of 40 nm, and the channel region 110 having a channel width of 2.5 μm and a channel length of 0.45 μm. The gate insulating film 162 includes the bottom insulating film 121 consisting of silicon dioxide film and having a film thickness of 10 nm, the silicon nitride film 122 having a film thickness of 20 nm, and the top insulating film 123 consisting of silicon dioxide film and having a film thickness of 15 nm. The top insulating film and the bottom insulating film use a so-called TEOS oxide film formed through the plasma CVD method using tetraetoxysilane. The gate electrode 131 consists of tungsten, and the inter-layer insulating film 103 includes silicon dioxide film. To this semiconductor element, 16 V is applied as the gate voltage Vg, 10 V as the drain voltage Vd, and 0 V as the source voltage Vs using the write circuit of FIG. 2.

FIG. 3 shows Id-Vg characteristics of before write, after write of 1 millisecond, after write of 10 milliseconds, and after write of 100 milliseconds. As shown in FIG. 3, the threshold value shift is about 1 V when the write time is 100 milliseconds.

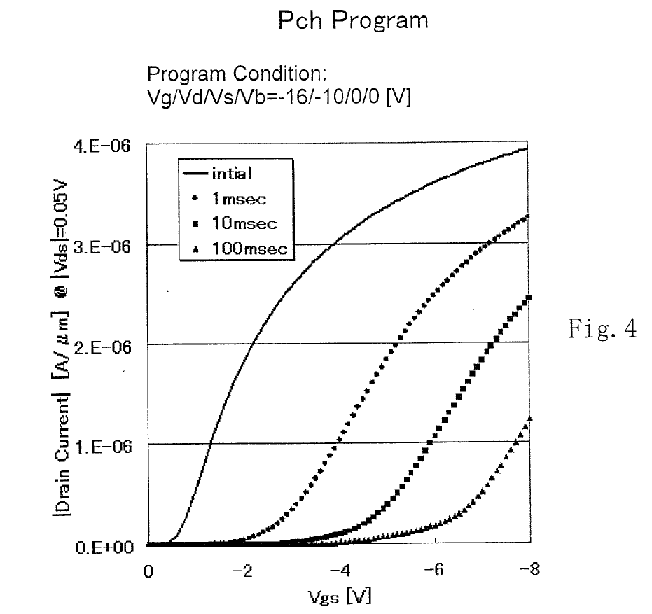

The memory element of the present invention, which is a P-channel type, uses the same elements as the semiconductor element used in the measurement of FIG. 3 other than that the conductivity-type is different. FIG. 4 shows Id-Vg characteristics of before write, after write of 1 millisecond, after write of 10 milliseconds, and after write of 100 milliseconds, where the threshold value shift is greater than 6 V when the write time is 100 milliseconds. Both write voltages have opposite signs, but have the same absolute value. That is, with the application to one diffusion layer region and to the body as a reference voltage, the absolute value of the gate voltage is 16 V, and the absolute value of the application voltage to the other diffusion layer region is 10 V.

As apparent from FIGS. 3 and 4, in the semiconductor storage element of the present invention, which is a P-channel type, the write speed is higher than the N-channel, and thus the memory window can be enlarged or high speed operation can be performed. In order to increase the write speed of the N-channel element, a so-called double gate structure including plural gate electrodes may be adopted. However, the manufacturing process becomes significantly complex in the double gate structure, and the manufacturing cost greatly increases. The merits of being a P-channel as in the present invention are considerably large in view of mass productivity.

The semiconductor storage element of the first embodiment arranged on the insulating substrate as described above has a feature of being formed as a P-type semiconductor element, whereby satisfactory characteristics that cannot be obtained if formed as an N-type semiconductor element can be obtained. The memory element of the first embodiment further has a unique feature and a unique mechanism as described below. This feature is, as described above, that Joule heat is generated by flowing current to the channel region between the diffusion layer regions 112 and 113, and the electron holes having sufficient energy to be injected are generated by such heat.

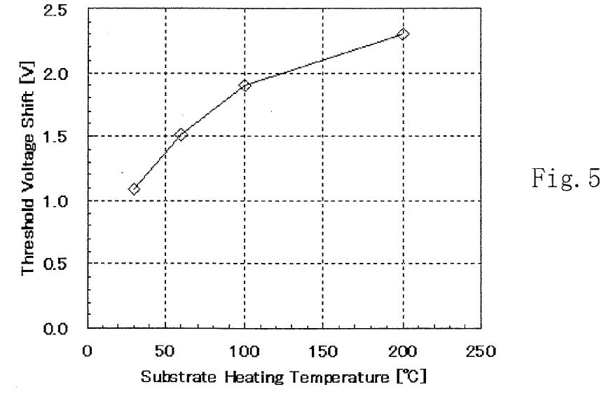

The element shown in FIG. 1 was heated with a heater and experimented to verify the above feature. In other words, experiment was conducted by attaching and mounting the semiconductor element used in the measurement of FIG. 4 on a plate incorporating a heater and a thermocouple, and measuring the heating temperature with the thermocouple. FIG. 5 shows the threshold value shift in write for every heating temperature. As shown in FIG. 5, the write speed increases the higher the temperature when the heater temperature is changed from 30° C. to 200° C. That is, a feature in that the electron hole injection efficiency to the gate insulating film becomes higher the higher the temperature of the semiconductor element is obtained, where the write speed can be increased or the voltage can be lowered by performing the write operation while heating the semiconductor element.

The element used has a channel length of 0.7 μm, channel width of 2 μm, and the structure of the gate insulating film of 15 nm of top insulating film (TEOS film), 20 nm of silicon nitride film, and 10 nm of bottom insulating film (TEOS film). The write condition is to have the gate voltage to −15 V and the drain voltage to −8 V with respect to the reference voltage (source voltage) and the write of 100 msec., and write is performed on the element in the initial state. The write is performed in such temperature, and the read is performed under room temperature.

The element of FIG. 1 was placed on the plate incorporating the heater for demonstration experiment, but a resistor element or a channel resistor may be arranged near the semiconductor element, and the semiconductor element may be heated by flowing current to the resistor element or the channel resistor. Heating the semiconductor element by channel resistor is the same as the semiconductor element of the present invention performing heat assistance.

In the first embodiment, a material having low thermal conductivity and high heat insulation performance such as glass is used for the insulating substrate 101, which provides an important effect in enhancing the write efficiency. In write, the Joule heat is generated by flowing current to the channel region, which is one type of resistor body, but since the heat insulation performance of the substrate 101 is high, the diffusion of the generated heat to the substrate side is suppressed, heat is likely to be held in the semiconductor element, and the temperature of the semiconductor element is effectively raised. As a result, an effect of promoting write similar to when the substrate is heated with heater is obtained.

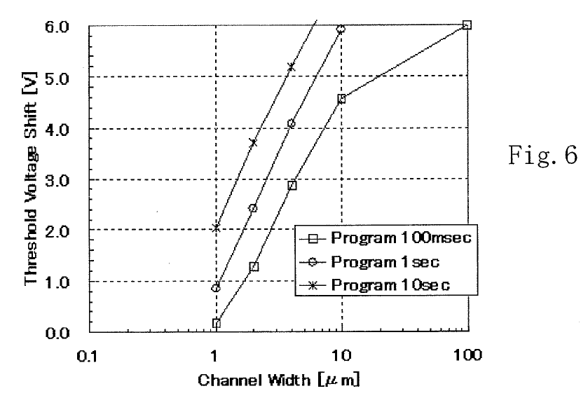

FIG. 6 shows a relationship between the threshold value shift amount in write and the channel width. The semiconductor element used in the measurement of FIG. 6 is the same as the semiconductor element used in the measurement of FIG. 5 other than the channel width, and the write and read voltage conditions are also the same. Measurement is performed using the semiconductor element of different channel width, and the relationship between the channel width and the write shift amount is plotted for the write time of 100 milliseconds, 1 second, and 10 seconds. According to FIG. 6, it can be seen that the shift amount is large and the write efficiency is enhanced the larger the channel width. The absolute amount of the current flowing to the element during write also becomes larger the larger the channel width of the element, whereby the total Joule heat generated per one semiconductor element of the present invention becomes larger. The semiconductor element of the present invention thus has higher device temperature during write, and higher write efficiency can be realized. If the current is too large, the temperature is raised in excess and may reach a high temperature of an extent of damaging the insulating substrate 101 and the semiconductor layer 161. Thus, when device driving as the memory element, the write efficiency becomes high by thermal effect and the current value is set to an extent high temperature of an extent of causing damages is not reached.

Furthermore, since the semiconductor layer 161 is arranged in island form and the inter-layer insulating film 165 with heat insulation performance is formed, the heat generated in write is suppressed from diffusing in the horizontal direction and in the vertical direction, and the temperature of the semiconductor element in write is effectively raised thereby promoting the write. That is, write can be carried out at a lower voltage.

The main write mechanism of the first embodiment is not FN tunneling current, nor generation of hot carriers by a so-called drain avalanche near the end of the diffusion layer region 113. The write mechanism of the present invention uses a unique mechanism of carrier generation at the entire surface of the channel region subjected to assistance of heat generated by current in write. This will be described below.

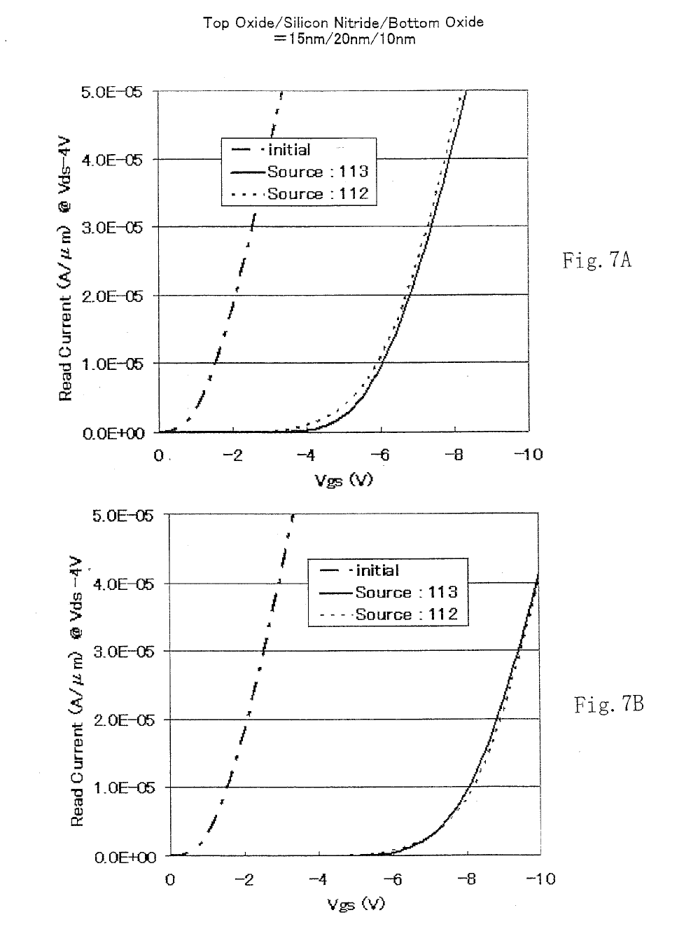

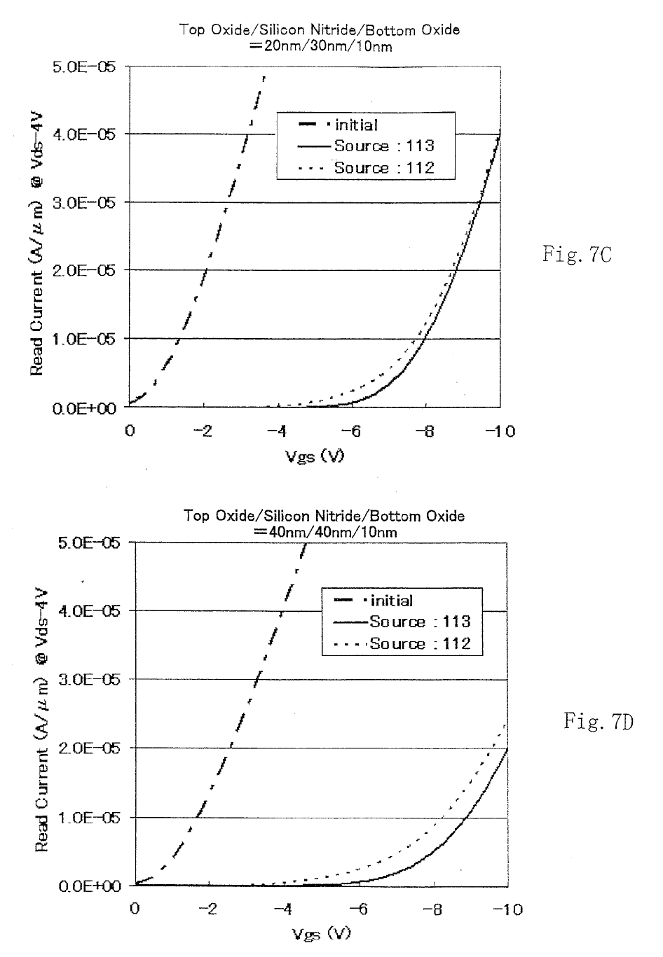

FIGS. 7A and 7B show Id-Vg characteristics of when read is performed at a higher drain voltage Vds=−4 V. FIGS. 7A and 7B show the initial characteristics before write is performed with a broken dashed line. The read characteristic when the diffusion layer region 112 is the drain and the diffusion layer region 113 is the source after write is performed is shown with a solid line. The read characteristic when the diffusion layer region 112 is the source and the diffusion layer region 113 is the drain is shown with a dotted line. Therefore, FIG. 7 compares the characteristics of read in both directions after write. The write condition is that the write gate voltage is −12 V in FIG. 7A and the write gate voltage is −15 V in FIG. 7B. The drain (diffusion layer region 113) voltage is −12 V, and the source (diffusion layer region 112) voltage is 0 V.

In either figure, the read characteristic when the diffusion layer region 113 is the source and the read characteristic when the diffusion layer region 112 is the source relatively match. For instance, with the gate voltage at where the read current becomes 10 μA/μm defined as the threshold value Vth, when the value is read as a point where the element sufficiently starts to be turned ON, the initial state is Vth=−1.54 V in FIG. 7A, whereas Vth=−6.04 V (threshold value shift amount ΔVth=−4.50 V) when the diffusion layer region 113 is the source and Vth=−5.91 V (threshold value shift amount ΔVth=−4.37 V) when the diffusion layer region 112 is the source after write. Therefore the difference in both read conditions is only 0.13 V. In other words, the difference in both read conditions with respect to the threshold value shift amount ΔVth from the initial state is about 3%. Similarly, in the case of FIG. 7B, the difference in both read conditions with respect to ΔVth is about 2%. Thus, both read conditions show very close characteristics. This shows that the distribution of the electron holes injected and trapped in the gate insulating film 162 at the upper side of between the diffusion layer regions 112 and 113 is distributed substantially left-right symmetric in the left and right direction (channel length direction) of the plane of drawing of FIG. 2.

The semiconductor element used in the measurement of FIGS. 7A and 7B has a channel length of 0.7 μm, a channel width of 4 μm, and a configuration of the gate insulating film of 15 nm for the film thickness of the top oxide (TEOS oxide film) 123, 20 nm for the film thickness of the silicon nitride 122, and 10 nm for the film thickness of the bottom oxide (TEOS oxide film) 121.

If the mechanism of write originates from the generation of hot carriers by the so-called drain avalanche near the end of the diffusion layer region 113, the charges generate near the end of the diffusion layer region 113, and thus the accumulated charges are also mainly localized in the gate insulating film 162 near the end of the diffusion layer region 113. If high drain voltage is set and read is performed in such situation, transistor operation is carried out in a so-called saturated region or in a state close thereto. Thus, the drain end is in the pinch off state or a state close thereto, and the difference in read currents is created depending on whether localization of the accumulated charges is on the drain side or the source side.

First, when read is performed with the diffusion layer region 113, which is the side the accumulated charges are localized, as the source and the diffusion layer region 112 as the drain in read, the read current is susceptible to the potential of the accumulated charges since the accumulated charges exist in the vicinity of the source, and the read current lowers. When read is performed with the diffusion layer region 112 as the source and the diffusion layer region 113 as the drain, the drain voltage is high, and the drain end is in a pinch off state or in a state close thereto. Thus, the influence of the accumulated charges localized on the drain side on the read current is reduced, and the read current does not lower as much as the previous case. As a result, significant difference in read current is created between both read conditions.

In read under high drain voltage of the first embodiment, however, such difference in characteristics is not created between both read conditions. This means that the distribution of accumulated charges in the gate insulating film 162 is substantially left-right symmetric rather than a left-right asymmetric charge distribution in which the charges are localized only in the vicinity of the diffusion layer region 113 (left-right is the left and right in the plane of drawing of FIG. 2). In other words, the charges are assumed to be more or less uniformly accumulated over the entire surface in the channel length direction. This is due to the fact that the main write mechanism of the first embodiment is a unique mechanism which uses carrier generation over the entire surface of the channel region subjected to assistance of heat generated by current in write. High speed write of less damage then can be performed by performing write with such mechanism.

In such write, the first embodiment alleviates the horizontal electric field in the vicinity of the drain end with the gate electric field by setting the gate voltage higher than the drain voltage with respect to the reference potential (source potential), and more effectively suppresses local hot carriers near the drain end. Therefore, the damages of the semiconductor element are prevented and the reliability of the memory can be enhanced. Furthermore, the gate electric field can be more effectively acted by reducing the thickness of the gate insulating film 162, and thus local hot carrier generation can be similarly suppressed and the reliability of the memory can be enhanced.

FIGS. 7C and 7D show Id-Vg characteristics when write and read are performed under the same write voltage condition as FIG. 7B with respect to the semiconductor element using the gate insulating film thicker than in FIG. 7B. Others are the same as FIG. 7B. The configuration of the gate insulating film including top oxide/silicon nitride/bottom oxide has film thicknesses of 20 nm/30 nm/10 nm in FIG. 7C, and 40 nm/40 nm/10 nm in FIG. 7D. The channel length and the channel width are the same. As apparent from such figures, a slight difference is created in the read characteristics in both directions the thicker the film thickness is, where the current is slightly lower in the solid line where the diffusion layer region 113, which is the drain in write, is the source in read. Performing the same calculation as in FIGS. 7A and 7B, the difference in both read conditions with respect to the threshold value shift amount ΔVth from the initial state when the diffusion layer region 113 is the source is about 4% in FIG. 7C and about 9% in FIG. 7D, and thus the difference is larger the thicker the film thickness is.

This shows that the accumulated charges are biased to the diffusion layer region 113 side in the semiconductor element with thick film thickness. That is, in addition to injection of charges from the entire surface of the channel region by heat assistance or the main write mechanism of the memory element of the first embodiment, the local hot carrier generation at the drain end also partially occurs. In other words, the effect of alleviating the horizontal electric field in the vicinity of the drain end with the gate electric field becomes weaker the thicker the gate film thickness, and high energy hot carriers generates at the drain end, whereby the semiconductor element may be damaged. In view of such aspect, the gate insulating film is preferably thin in electrical film thickness, so that generation of high energy hot carriers at the drain end can be more effectively suppressed. The charge distribution after write is substantially uniform without localizing at the drain end, that is, the distribution is a substantially symmetric potential distribution between both diffusion layer regions, and thus the characteristics are close to each other even if read is performed with the source and the drain interchanged. As the potential distribution is preferably uniform, the difference in characteristics is preferably small. The threshold value difference is preferably smaller than or equal to 10% with respect to the threshold value fluctuation amount by write.

As described above, the charges are accumulated in the charge accumulating film by charge injection from the entire surface of the channel region by heat assistance in the present invention. However, in the present invention, the charges accumulated in the charge accumulating film are not all limited to charge injection from the entire surface of the channel region by heat assistance. The hot carriers generated at the drain end may be injected as long as the semiconductor element is not damaged.

In FIG. 7D, the electrical film thickness converted by the dielectric constant is about 60 nm in silicon dioxide film conversion, and is preferably thinner. More preferably, the generation of hot carriers at the drain end can be more effectively suppressed by obtaining a gate insulating film of 45 nm in silicon dioxide film conversion, as in the case of FIG. 7C. Furthermore, as shown in FIGS. 7A and 7B, the accumulated charges become substantially uniform on the channel by thinning the electrical film thickness of the gate insulating film to 35 nm in silicon dioxide film conversion, the generation of hot carriers at the drain end is satisfactorily suppressed, and a semiconductor element having an extremely high reliability is obtained.

If the gate insulating film is too thin, the device characteristics may vary due to influence of variation in film thickness, the pressure resistance of the gate insulating film becomes low and thus may break the device, and the charge holding characteristic may degrade as described above. Thus, the top oxide/silicon nitride/bottom oxide are respectively greater than or equal to 5 nm/10 nm/5 nm, that is, greater than or equal to 15 nm in the electrical film thickness of the silicon dioxide film conversion. Therefore, 15 nm to 45 nm is the preferred range in the electrical film thickness of the silicon dioxide film conversion.

Alternatively, since it is preferred to thin the electrical film thickness of the gate insulating film and to not have the actual film thickness too thin, it is effective to use hafnium oxide, zirconium oxide, and the like having higher dielectric constant than the silicon nitride for the charge accumulating film.

Therefore, in the first embodiment, the thermal conductivity takes a value of between about 0.5 and 1.5 W/m·K as a typical value when the glass substrate is used. Since a material having high heat insulation performance is used for the substrate 101, the heat generated by current in write is prevented from escaping to the substrate side as much as possible, and the temperature of the semiconductor element can be effectively raised with such heat. The write efficiency enhances with increase in temperature, and efficient write using heat generated by the semiconductor element itself can be realized.

Forming the semiconductor layer 161 to island form, and forming the inter-layer insulating film 165 are effective in concentrating heat in the memory element. That is, if glass substrate or resin substrate is used for the substrate as in the first embodiment, the merit of producing at low cost is obtained since the substrate is cheap, and the merit of increasing the write speed using heat is obtained as described above since the thermal conductivity is low and the heat insulation performance is high.

Furthermore, higher write speed is obtained the larger the channel width, as shown in FIG. 6. This is due to the fact that the temperature tends to easily rise since the current between the source and the drain of the semiconductor element is large and the calorific value is large. Therefore, the merit in that write can be performed at higher speed or lower voltage the larger the channel width can be obtained.

The channel width is larger than 100 μm, where the current amount in write is very large if set to 200 μm and the like, and thus is susceptible to voltage drop by parasitic resistance and heat radiation effect can be enhanced by increasing the area of the semiconductor element itself, whereby the enhancement in write speed is not as great as when the channel width is 100 μm. The power consumption may increase, the area of the peripheral circuit may increase, or the wiring may be damaged or broken by increase in current amount, and thus the channel width is preferably set to smaller than or equal to 100 μm.

The variation for every semiconductor element becomes large if the channel width is smaller than 0.5 μm such as 0.3 μm. Thus, the channel width is preferably greater than 0.3 μm.

Therefore, the preferred channel width is between 0.5 μm and 100 μm. In particular, the variation is suppressed and the current amount is made relatively small, and furthermore, the suitable channel width may be a value between 2 μm and 20 μm, where 5 μm is set as one example of a preferred channel width in the first embodiment.

The channel length has a problem in that the write speed becomes very slow when the channel length is too large, and thus is preferably smaller than or equal to 5 μm. If the channel length is smaller than 0.1 μm, the influence of short channel effect becomes large, and the variation among semiconductor elements becomes large, and thus the channel length of greater than or equal to 0.1 μm is preferable.

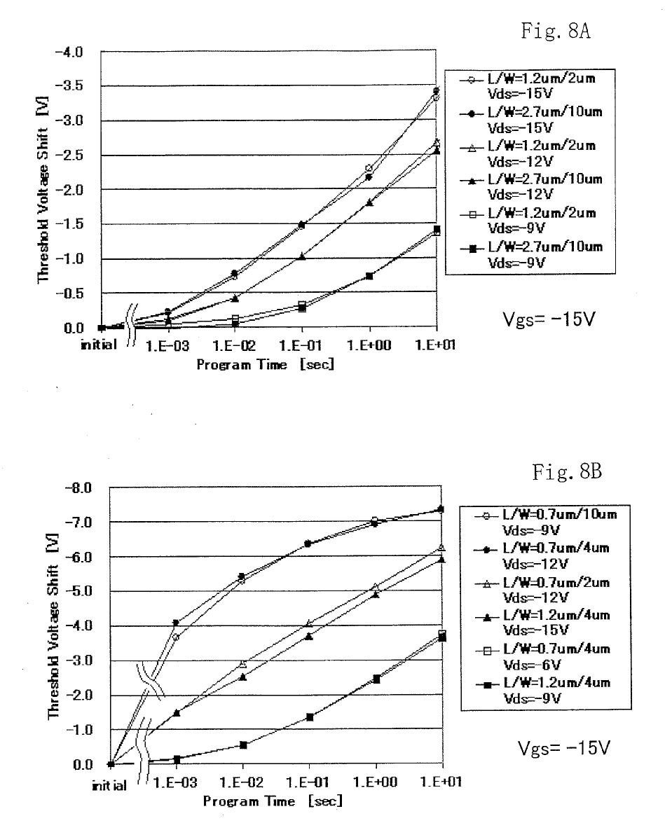

The dependence of the write speed on the channel length L, the channel width W, and the write drain voltage Vds will now be described. FIG. 8 shows examples of the write characteristic at various channel length L, channel width W, and write drain voltage Vds. The configuration of the gate insulating film is top oxide (TEOS film) of 15 nm, silicon nitride of 20 nm, and bottom oxide (TEOS film) of 10 nm. In all cases, the voltage in write is source voltage of 0 V and gate voltage Vgs of −15 V, but the read drain voltage is −0.05 V. The graph represents the voltage application time on the horizontal axis and the amount the threshold value shifted from the initial state by write on the vertical axis, where the threshold value shifts to negative by write since the electron holes are injected to the P-channel semiconductor element.

FIG. 8A is an example where the write characteristics for the semiconductor element of L=1.2 μm/W=2 μm and the semiconductor element of L=2.7 μm/W=10 μm are measured and compared for the drain voltage Vds of −9 V, −12 V, and −15 V (respectively displayed in circle, triangle, and square). According to such graph, the write characteristics of the semiconductor element of L=1.2 μm/W=2 μm and the semiconductor element of L=2.7 μm/W=10 μm have similar characteristics at all the drain voltages.

FIG. 8B shows an example of the write characteristics at three different channel length L, channel width W, and write drain voltage Vds.

(a) The write of Vds=−9 V to the semiconductor element of L=0.7 μm/W=10 μm and the write of Vds=−12 V to the semiconductor element of L=0.7 μm/W=4 μm have close write characteristics (circle in the graph).

(b) The write of Vds=−12 V to the semiconductor element of L=0.7 μm/W=2 μm and the write of Vds=−15 V to the semiconductor element of L=1.2 μm/W=4 μm have close write characteristics (triangle in the graph).

(c) The write of Vds=−6 V to the semiconductor element of L=0.7 μm/W=4 μm and the write of Vds=−9 V to the semiconductor element of L=1.2 μm/W=4 μm have close write characteristics (square in the graph).

The features of (a), (b), and (c) can be read.

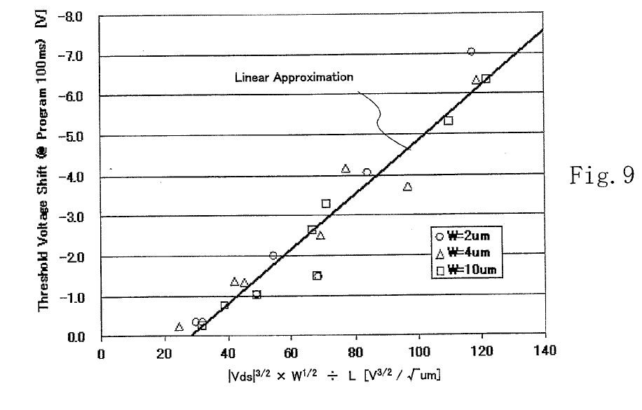

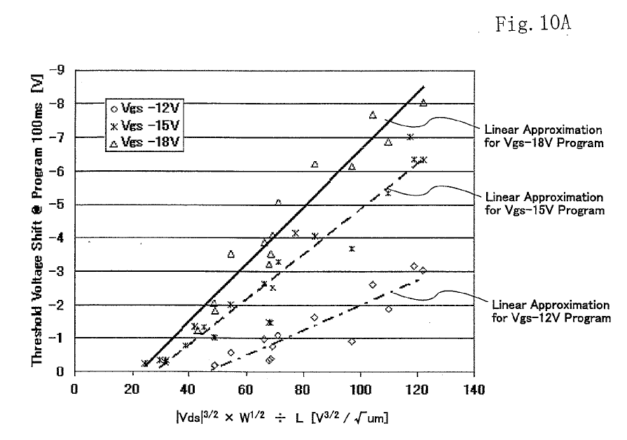

Thus, in addition to the feature in that the write speed becomes higher the smaller the channel length, or the larger the channel width, or the higher the drain voltage, the following empirical rules can be found. The empirical rule is that the write speed more or less depends on the value obtained by multiplying square root of the value of the channel width W to the absolute value of the drain voltage value Vds raised to the 3/2 power and dividing the resultant with the value of the channel length L. This is shown in FIG. 9. The channel length is appropriately taken between 0.7 μm and 2.8 μm, the channel width between 2 and 10 μm, and the drain voltage between −6 and −15 V, and the write shift amount when write is performed is shown. The horizontal axis shows the value of |Vds|^{3/2}×W^{1/2}÷L and the vertical axis shows the shift amount when write is performed for 100 milliseconds (unit of Vds is V, the unit of channel width W is μm, and the unit of channel length L is μm). In this case, there is a correlation between the values without depending on the value of W at least in this measurement range, and the write speed becomes higher the higher the value of |Vds|^{3/2}×W^{1/2}÷L.

This tendency is merely an empirical rule but can be qualitatively understood as below. The write speed is influenced by the temperature of the channel part as described above, but is also contributed by the horizontal electric field of the channel part, where the write efficiency is assumed to enhance the stronger the horizontal electric field. Here, the channel is approximately assumed as simply a resistance, the resistance value being assumed as R, and the calorific value P is expressed as P=|Vds|²/R, and thus the R is proportional to L and inversely proportional to W. Therefore, P depends on |Vds|²×W/L, and the device temperature also depends on the value of |Vds|²×W/L. The horizontal electric field of the channel part is expressed as |Vds|/L if the channel is approximately assumed as an even resistor body.

Since the write speed is influenced by two parameters, the value of |Vds|²×W/L and the value of |Vds|/L, the contribution (large write efficiency with large |Vds|) is larger with Vds with respect to the dependence on L (large write efficiency with small L), and the contribution of W (large write efficiency with large W) is assumed to be not as large as L. Thus, through the use of the value of |Vds|^{3/2}×W^{1/2}÷L, which is merely a square root of the product obtained by simply multiplying the two parameters, it is not precise but can be used as an approximate parameter that reflects the write efficiency.

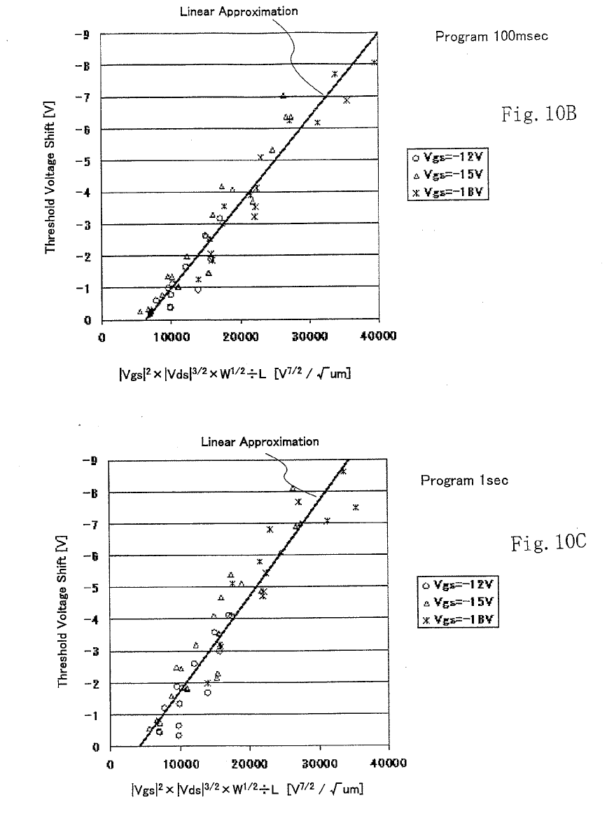

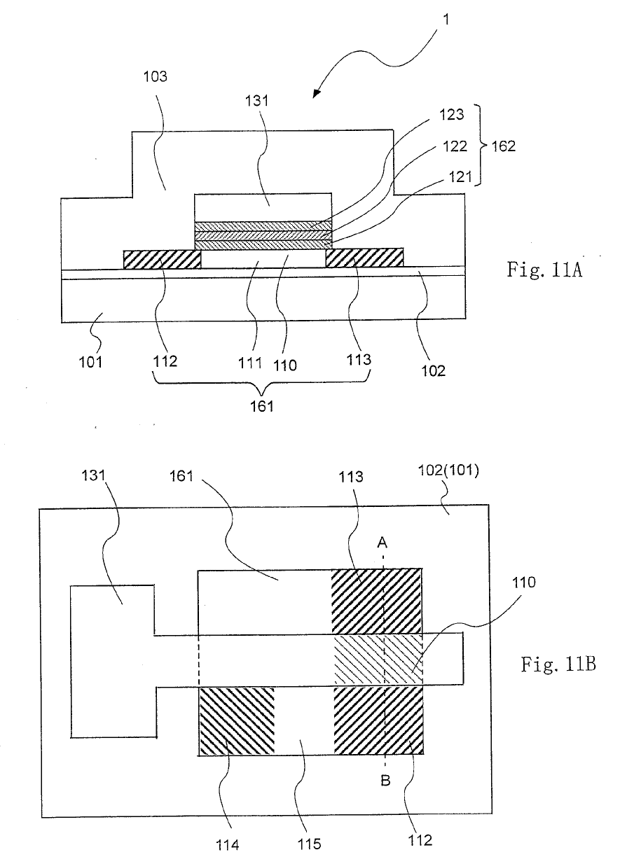

Furthermore, the voltage Vgs of the gate electrode also contributes to write efficiency. Since the channel resistance lowers the higher the absolute value of the Vgs, the calorific value increases, the generated carriers are more strongly attracted in the gate electrode direction, and the write efficiency can be enhanced. FIG. 10A shows a plot of FIG. 9 for each write speed of Vgs=−12 V, −15 V, and −18 V. From the figure, it can be seen how to set the Vds, the Vgs, the channel length, and the channel width to obtain the desired write speed. For instance, when having the absolute value of Vgs to greater than or equal to 15 V, the value of |Vds|^{3/2}×W^{1/2}÷L is set to greater than or equal to 60, so that a threshold value shift of about −2 V can be predicted to be obtained. If greater than or equal to 80, the predicted threshold value shift reaches −4 V, and a large window can be obtained.

The tendency shown in FIGS. 9 and 10A is a tendency significantly seen in the semiconductor element having W of up to about 20 μm, and does not necessarily apply for the semiconductor element having greater W value such as W of 100 μm. If W is small, the influence of area etc. of the contact plug part on the gate electrode and the diffusion layer region with respect to the size of the semiconductor element is large, and there is no large difference in the device size itself between semiconductor elements having different W. Thus, the calorific value is satisfactorily reflected on the device temperature. However, if W is very large, the magnitude of W is reflected on the device area as is, whereby the heat radiation efficiency becomes higher the larger the calorific value in write, whereby the calorific value dependence is assumed to become smaller than with small W.

The write efficiency enhances the larger the absolute value of the Vgs, but the influence thereof is large. This aspect is also related to the unique mechanism of the memory element of the first embodiment. In the memory of a type using mainly drain avalanche for carrier injection in write, the horizontal electric field near the drain end greatly influences the write efficiency. Thus, the influence of the drain voltage on the write speed is large, where the force for attracting the generated carriers in the gate direction becomes stronger if the gate voltage is raised, but the gate electric field acts in a direction of alleviating the horizontal electric field of the drain end. Therefore, both effects act in the directions of canceling each other out, and consequently, the gate voltage may not greatly influence the write speed as much as the drain voltage.

The main write mechanism of the memory element of the first embodiment is not the write mechanism using drain avalanche, but is carrier injection from the entire surface of the channel region using heat generation effect by the channel current, as described above. Thus, increase in the write gate voltage leads to mutual effect of increase in Joule heat by lowering in channel resistance and increase in the force of attracting the generated carriers by the gate electric field. The write efficiency is then significantly raised.

FIGS. 10B and 10C takes the effect of the Vgs on the parameter of the horizontal axis, and plots the value of |Vgs|²×|Vds|^{3/2}×W^{1/2}÷L on the horizontal axis (unit of Vgs and Vds is V, and unit of W and L is μm). FIG. 10B is a graph of when the write is 100 milliseconds, and FIG. 10C is a graph of when the write is 1 second. In this case, the graph of the threshold value shift amount representing the write speed more or less draws the same curve irrespective of the value of Vgs. At the parameter of the horizontal axis, Vgs is taken at higher dimension than Vds (Vds is 1.5 power whereas Vgs is 2 power) to indicate that the influence on the write efficiency of the Vgs is very large. An appropriate device design is made in view of such characteristics. If the horizontal axis parameter |Vgs|^{2x}|Vds|^{3/2}×W^{1/2}÷L is greater than or equal to 15000, the threshold value shift of about −2 V is obtained at write of 1 second, and thus is a preferred condition. If the value of the horizontal axis parameter exceeds 40000, the device may break, and thus close attention is required.

### Second Embodiment

A second embodiment of the present invention will now be described using FIG. 11.

FIG. 11A is a cross-sectional frame format view taken along line A-B of FIG. 11B, and FIG. 11C is a plan frame format view. Similar, to the first embodiment, the cross-sectional structure has the body region 111 and the P-type diffusion layer regions 112, 113 arranged in the semiconductor layer 161, the surface of the body region 111 between the P-type diffusion layer regions 112 and 113 forming the channel region 110, and the charge accumulating film 162 and the gate electrode 131 existing on the upper part thereof.

The second embodiment has a feature in that an electrode terminal (not shown) for controlling the potential of the body region is arranged contacting the body region 111. As a most preferred mode, one example is as shown in FIG. 11B, where one part of the body region 111 is a body contact region 114 having a conductivity-type of N-type, and the electrode terminal (not shown) is arranged so as to contact at least one part of the body contact region 114. As an example of realizing the same, the above structure is obtained by installing a contact plug made of metal on the body contact region 114. The contact resistance between the electrode terminal and the body region 111 is low, ohmic connection is obtained, and the controllability of the body potential is enhanced. In the semiconductor storage device of the second embodiment, as hereinafter described, the body potential is controlled through the electrode terminal arranged in the body contact region 114 in the erase operation to realize high speed erase at a relatively low voltage.

FIG. 11B shows, in frame format, a plane structure of when the body contact region 114 is arranged in the semiconductor layer 161 on the same side as the diffusion layer region 112 with respect to the gate electrode 131. In order to adopt such structure, the body contact region 114 and the diffusion layer region 112 are not brought close, and are preferably arranged with a distance of a certain extent. This is because since the semiconductor layer 161 is arranged on the insulating substrate, the crystalline property is not necessarily high and may contain crystal defects and the like. Therefore, if the diffusion layer region 112 or the high concentration P-type semiconductor region and the body contact region 114 or the high concentration N-type semiconductor region are brought close to form a steep PN junction, junction leakage current caused by the defect may generate. In particular, when driving a plurality of memory elements, such junction leakage occurs in a non-selected memory cell. As a result, increase in power consumption and operation abnormality may occur.

To prevent this, the body contact region 114 and the diffusion layer region 112 are preferably separated by a distance of greater than or equal to 2 μm, and a semiconductor layer region 115 of low concentration is preferably arranged in between. The body contact region 114 and the diffusion layer region 112 can be separated the larger the width of the low concentration semiconductor layer 115, but the device area of the semiconductor element increases if the width is too large, and thus is not preferable. Therefore, the width is preferably smaller than or equal to 20 μm. The concentration of the semiconductor layer 115 is between about 5×10¹⁶cm⁻³ and 2×10¹⁸cm⁻³.

The body contact region 114 may be arranged on the diffusion layer region 113 side or on both sides of the gate electrode 131.

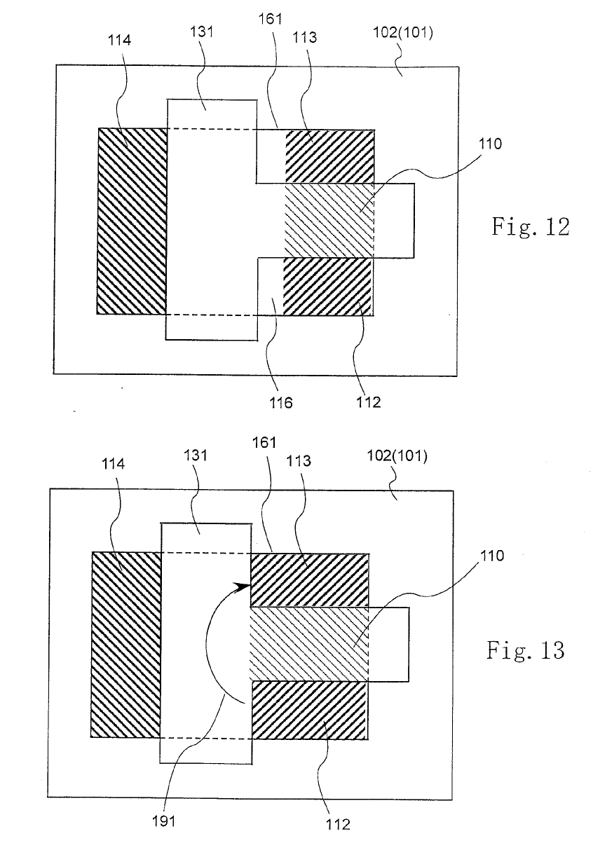

As another further preferred plane structure mode, the body contact region 114 may be arranged in a form shown in the plan view of FIG. 12. In the case of FIG. 12, the gate electrode 131 is arranged in a form of separating the diffusion layer region 112 and the diffusion layer region 113. At the same time, the gate electrode 131 is also arranged in a form of separating the body contact region 114 and the diffusion layer region 112, 113. That is, the semiconductor layer 161 is partitioned into at least three regions of a portion including the diffusion layer region 112, a portion including the diffusion layer region 113, and a portion including the body contact region 114 by the gate electrode 131. In the case of such plane structure, the semiconductor layer 161 under the gate electrode 131 is depleted by the potential of the gate electrode 131, and the space between the diffusion layer region 112, 113 and the body contact region 114 is divided by the depleted layer in the memory element of non-selected state. Thus, the insulating property in between is high and leakage current is less likely to occur, and thus increase in power consumption and occurrence of abnormal operation can be suppressed.

To obtain such structure, the gate electrode 131 is formed to a T-shape in FIG. 12 by way of example. In this case, the diffusion layer regions 112, 113 are arranged spaced apart from the site of the gate electrode 131 corresponding to the crossbar of the T-shape, and a low concentration semiconductor layer 116 preferably exists in between. When the diffusion layer regions 112, 113 are contacting the crossbar of the T-shape of the gate electrode 131 (FIG. 13), leakage current 191 generates between the diffusion layer regions in the semiconductor layer 161 under the crossbar part of the T-shape during the read operation. The magnitude of the read current influences the held charges of the charge accumulating film on the channel region 110, whereby the element of the second embodiment functions as a memory. However, the leakage current 191 has small influence of held charges, and current flows even if the memory is in the write state, and thus the read current in the write state increases compared to the structure of FIG. 12.

In the structure of FIG. 12, the influence of such leakage current is further suppressed small, and the read current amount of the write state can be reduced. In other words, the ratio of the read current in the erase state and the read current in the write state can be increased in the structure of FIG. 12, and thus stable read becomes possible and a memory device of higher reliability is obtained. Therefore, both or at least one of the diffusion layer regions 112, 113 are preferably arranged so as to contact the gate electrode 131 only at the site facing the channel region 110.

The memory element of the second embodiment of the present invention can be formed through the process similar to the first embodiment, where the body contact region 114 may be formed in the semiconductor layer 161 in before, after or simultaneously with the formation of the P-type diffusion layer region. The formation of the body contact region 114 may use ion injection method or solid-phase diffusion method, similar to the formation of the P-type diffusion layer regions 112, 113. The impurities providing a conductivity-type of N-type are introduced to a region to become the body contact region 114, and thereafter, annealing treatment is appropriately performed to form the body contact region 114. When performing the annealing treatment, it may be performed simultaneously with the annealing in forming the P-type diffusion layer regions 112, 113 or may be separately performed. When annealing is simultaneously performed, the number of processes is reduced, which is advantageous in terms of manufacturing cost.

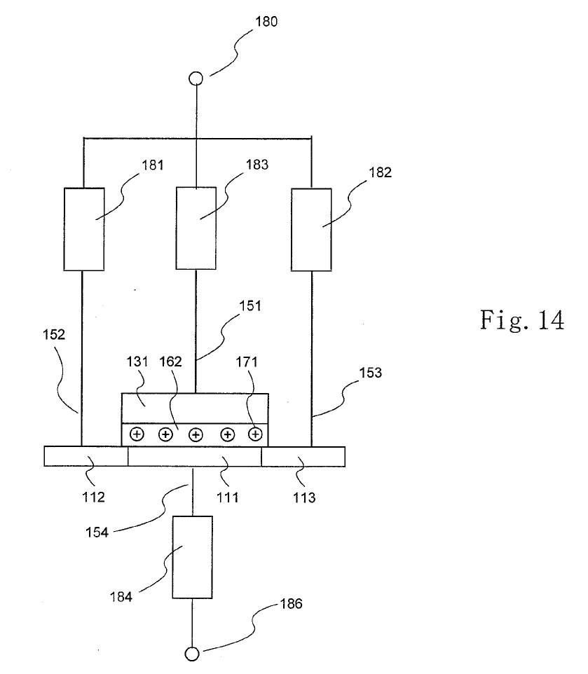

The write method serving as the operation method related to information storage of the memory element according to the second embodiment complies with the method of the first embodiment. As shown in FIG. 14, the first reference voltage is applied via the first voltage application circuit 181 from the DC power supply 180 to the terminal 152 connected to one P-type diffusion layer region 112. A write voltage negative with respect to the reference voltage (e.g., −6 V to −14 V with respect to reference voltage) is applied via the second voltage application circuit 182 from the DC power supply 180 to the terminal 153 connected to the other P-type diffusion layer region 113. A voltage negative with respect to the reference voltage (e.g., −6 V to −18 V with respect to reference voltage) is applied via the third voltage application circuit 183 from the DC power supply 180 to the terminal 151 connected to the gate electrode 131. A reference voltage is applied via a fourth voltage application circuit 184 from a power supply 186 to a terminal 154 connected to the body contact region connected to the body region 111.

The first voltage application circuit 181, the second voltage application circuit 182, the third voltage application circuit 183, and the fourth voltage application circuit 184 are respectively configured including a switching element, similar to the first embodiment, which switching element is selectively controlled with the timing of voltage application, the voltage application time and the order of voltage application by a decoder circuit (not shown).

In this case, the current generates in the channel region between the diffusion layer regions 112 and 113, electron holes having sufficient energy to be injected to the gate insulating film 162 or the charge accumulating film are generated by heat, and then injected to the gate insulating film 162 (electron hole 171) to carry out write.

The read operation of the memory element of the second embodiment is also performed in compliance with the method of the first embodiment, the current flowing between the diffusion layers is detected by transistor operation, and the write state is read by the magnitude thereof.

In the second embodiment, the terminal 154 is connected to the body contact region 114, but voltage may be applied through the fourth voltage application circuit 194 from the DC power supply 186 to the terminal 154 in write or read. Alternatively, a so-called floating state may be obtained without applying voltage. Application of voltage is preferable in terms of device operation control, where the same reference voltage as the terminal 152 is applied in write in the second embodiment. One part of the carriers generated secondarily are also discharged from the body contact region 114 in write, and thus the controllability of the body potential increases and operation variation among the semiconductor elements is suppressed. In the second embodiment, the same voltage as the source is applied to the terminal 154 in read. If transistor operated with the diffusion layer region 112 as the source and the diffusion layer region 113 as the drain in read, the same voltage as the terminal 152 is preferably applied.

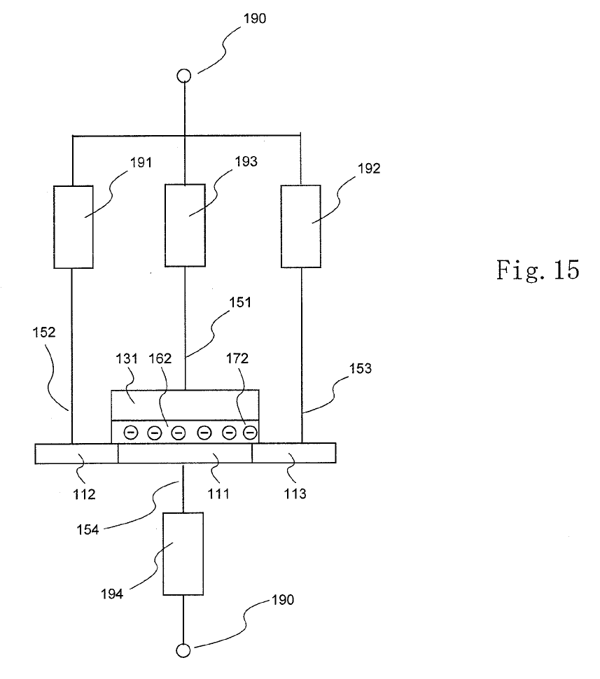

The erase method will now be described as an operation method related to information storage of the memory element of the second embodiment of the present invention. As shown in FIG. 15, in erase, an erase reference voltage is applied via fifth and sixth voltage application circuits 191, 192 from a DC power supply 190 to the terminals 152, 153 connected to the two diffusion layer regions 112, 113. An erase voltage positive with respect to the erase reference voltage (e.g., 6 V to 24 V with respect to erase reference voltage) is applied via a seventh voltage application circuit 194 from the DC power supply 190 to the terminal 154 connected by way of the body contact region to the body region 111. An erase voltage positive with respect to the erase reference voltage (e.g., 6 V to 30 V with respect to erase reference voltage) is applied via an eighth voltage application circuit 193 from the DC power supply 190 to the terminal 151 to the gate electrode 131.

Similar to the first embodiment, the fifth voltage application circuit 191, the sixth voltage application circuit 192, the seventh voltage application circuit 193, and the eighth voltage application circuit 194 are respectively configured including a switching element, which switching element is selectively controlled with the timing of voltage application, the voltage application time and the order of voltage application by a decoder circuit (not shown). The fifth voltage application circuit 191, the sixth voltage application circuit 192, the seventh voltage application circuit 193, and the eighth voltage application circuit 194 may be a common circuit with the first voltage application circuit 181, the second voltage application circuit 182, the third voltage application circuit 183, and the fourth voltage application circuit 184 of the second embodiment by adjusting the application voltage.

In this case, an electron accumulating layer is formed in the body region 111 near the boundary with the gate insulating film 162 by the potential of the gate electrode 131. The electron accumulating layer is controlled to the erase voltage by the body terminal 154, where a junction applied with strong reverse bias is formed between the P-type diffusion layer regions 112, 113 applied with the erase reference voltage. At the junction part, reverse direction leakage current generates from the strong reverse bias, and high energy carriers are secondarily generated with further acceleration of the electric field. Among the generated carriers, one part of the electrons are pulled by the potential of the gate electrode 131 and injected to the gate insulating film 162 (electron 172), and erase is carried out. If read is performed with the erase performed, the read current flowing between one diffusion layer region 112 and the other diffusion layer region 113 increases more than the read current in the write state.

In the erase operation, in particular, erase of higher speed becomes possible by setting the erase voltage to the gate electrode 131 higher than the erase voltage to the body region 111. The potential of the gate electrode 131 is set higher than the potentials of the diffusion regions 112, 113 and the body region 111, so that the generated electrons can be effectively pulled in the direction of the gate electrode 131 (upward direction in plane of drawing of FIG. 15) by the electric field, and the speed of erase can be increased.

The reference voltage in erase may be matched with the ground potential, or the potential other than the ground potential may be used as necessary. For instance, each voltage example of when the reference voltage is −12 V is −6 V to 12 V for the body contact region 113, and −6 V to 18 V for the gate electrode 131. In this case, the absolute value of the voltage to be applied to each terminal can be suppressed, and thus the peripheral circuit for supplying voltage can be simplified.

In the above description, the voltage is simultaneously applied to the two diffusion layer regions in erase, but may be separately applied. However, the erase can be completed in a short period of time if simultaneously applied as described above.

In write of the second embodiment described above, the electron holes are injected to the gate insulating film 162 from the entire surface of the channel region, whereas the electron injection in erase described here is mainly carried out in the vicinity of the boundary of the diffusion layer regions 112, 113 and the body region 111. However, such electron injection is spread to a certain extent, so that the accumulated electron holes can be erased. This aspect will be hereinafter described in more detail below.

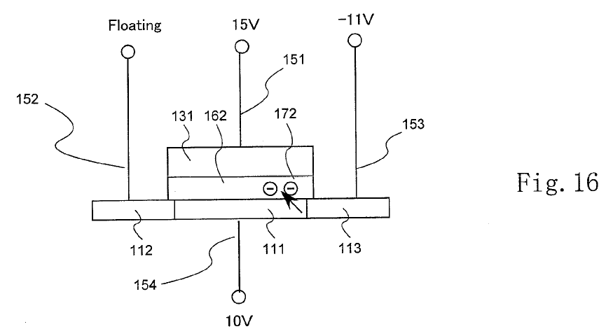

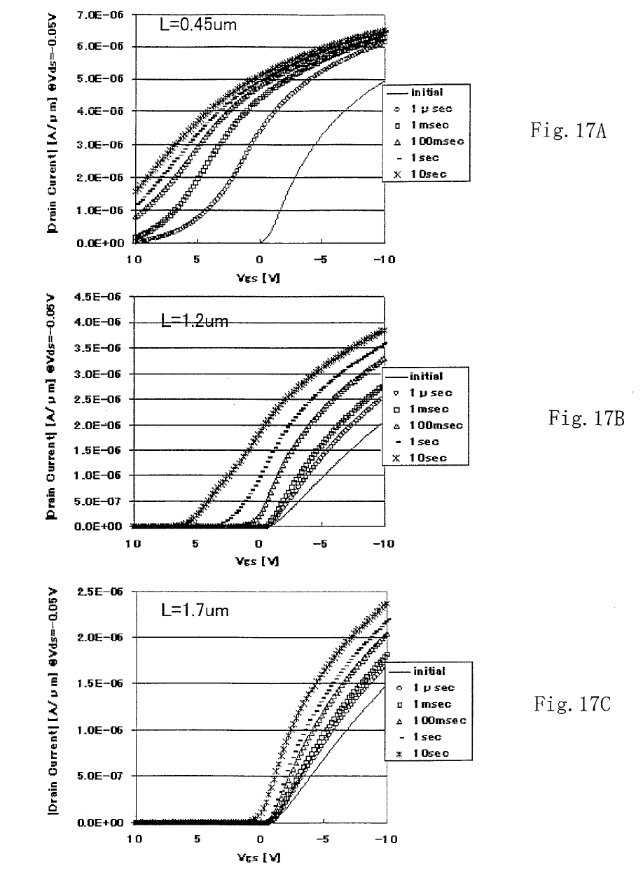

An experiment shown in FIG. 16 was performed to examine to what extent of the range the electrons are injected from the end of the diffusion layer region towards the middle of the channel in erase. The diffusion layer region 112 is in a floating state, and the erase voltage is applied only to the diffusion layer region 113 side. The erase voltage was −11 V. 15 V was applied to the gate electrode 131, and 10 V was applied to the body 111. The electron injection by the erase mechanism was performed only near the end of the diffusion layer region 113, and was practically not performed on the diffusion layer region 112 side. Such erase was applied to the semiconductor element having different channel lengths, and the read characteristics were compared. FIGS. 17A, 17B, and 17C show the read Id-Vg characteristics of when the channel length is 0.45 μm, 1.2 μm, and 1.7 μm. The read condition is a drain voltage of −0.05 V or a linear condition to sensitively reflect the influence of the held charges on the threshold value of the read Id-Vg. The erase time is between 1 μsec and 10 seconds. The semiconductor element used here has a channel width of 5 μm, and the film configuration of the gate insulating film is 40 nm of top oxide (TEOS film), 40 nm of silicon nitride, and 10 nm of bottom oxide (TEOS film).

First, focusing on the characteristics for the channel length of 0.45 μm of FIG. 17A, it can be seen that the entire Id-Vg curve shifts to the erase side by simply performing erase for 1 μsec. That is, the spread of the electron injection generated at the diffusion layer end on one side has a spread enough to cover the entire surface of the channel of 0.45 μm, and the electrons are injected to the entire surface of the channel.

Focusing on the characteristics for the channel length of 1.2 μm of FIG. 17B, it can be seen that the rising point of the Id-Vg graph is barely shifted in the erase of a short period of time of erase of 1 μsec or 1 msec, and increase in the slope of the graph, that is, rise in Gm value is found. This shows that the injected electrons from the end of the diffusion layer region 113 does not reach the vicinity of the end of the other diffusion layer region 112.

The read is a read of a linear region of low Vds value, where if a portion where the threshold value is locally high exists in the direction of the channel length, the threshold value of the relevant portion is reflected as the threshold value of the semiconductor element itself. That is, electron injection is performed near the end of the diffusion layer region 113, and lowering in threshold value (shift to the direction of positive value as the semiconductor element is a P-type semiconductor element) locally occurs. However, the threshold value shift does not occur in the vicinity of the end of the diffusion layer region 112 to which the injected electrons have not reached, which is reflected on the threshold value in the Id-Vg curve. The rising point of the graph is thus assumed to be unchanged. Lowering in the threshold value near the end of the diffusion layer region 113 contributes to decrease in channel resistance, and thus the slope of the graph increases.

As described, in the semiconductor element, the erase of the entire channel region from the diffusion layer region 113 to the diffusion layer region 112 is barely recognized in the erase of up to 1 millisecond. In the erase of greater than or equal to 100 millisecond, the shift of the rising point of the graph, that is, injection of electrons to the entire channel region is recognized. That is, if erase is performed for at least 100 millisecond, the electrons can be injected even to the point distant by 1.2 μm from the end of the diffusion layer region.

Furthermore, if the channel length is 1.7 μm as shown in FIG. 17C, the threshold value shift is barely seen up to the erase of 1 second, and increase in Gm is mainly recognized. The threshold value shift occurs at 10 seconds of erase. That is, if erase is performed for 10 seconds, the electrons are injected even to the point distant by 1.7 μm from the end of the diffusion layer region.

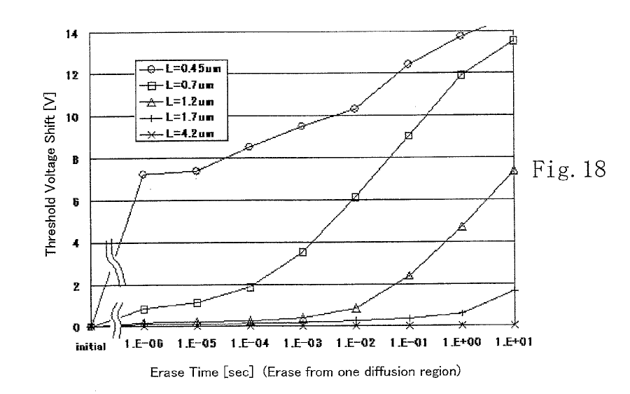

From such standpoints, the relationship between the erase time and the threshold value shift of when erase is performed only from the diffusion layer on one side is shown in FIG. 18. When the channel length is large or 4.2 μm, the threshold value shift is not recognized in the measurement range. When the channel length is 1.2 μm and 1.7 μm, respectively, as shown in FIGS. 17B and 17C, the threshold value shift barely occurs when the erase time is a short period time, but the threshold value shift occurs as the erase time becomes longer. That is, even if electron injection is carried out at the end of the diffusion layer region, the electrons can be injected to the site distant by a certain extent by extending the erase time. If the erase time is 10 seconds, the electrons can be injected even to the site distant by 1.7 μm from the end of the diffusion layer region 113.

In the experiment here, the electrons are injected only from the diffusion layer region on one side, but if the electrons are injected at the ends of both diffusion layer regions, the electrons can be injected to the position distant by 1.7 μm from the end of the diffusion layer region 112 and the position distant by 1.7 μm from the end of the diffusion layer region 113. That is, if the channel length is smaller than or equal to 3.4 μm, the electrons can be injected to the entire channel region. If the channel length is greater, the electron injection in erase may not reach to the middle of the channel even if erase is carried out from the end of both diffusion layers.

When attempting to erase the memory element in write state, the electron hole charges by write may effectively remain at the middle of the channel even after erase. This electron hole inhibits the current in read, and thus the read current of the erase state does not sufficiently increase with respect to the write state, and the current difference in the write state and the erase state or the so-called memory window becomes small, which lowers the reliability as a memory. If rewrite is repeatedly performed in such state, the read current of the erase state further lowers, and detection of the write state and the erase state may become difficult. In order to enlarge the write/erase window even after the rewrite is performed and to enhance the reliability of the memory, it is important to inject the electrons up to the middle of the channel and erase the accumulated electron holes in erase. However, the erase voltage or the erase time for injecting the electrons to the middle of the channel becomes longer as the longer the channel length is.

Therefore, the channel length is preferably smaller than or equal to 3.4 μm. Furthermore, in the semiconductor element having a channel length of 1.2 μm in FIG. 18, the threshold value of about 4.7 V is obtained in erase of 1 second and a large shift of 7.3 V is obtained in erase of 10 seconds. In order to electrically neutralize the accumulated electron holes sufficiently in the write state, and repeatedly perform a stable rewrite, the channel length of double the length, that is, the channel length of smaller than or equal to 2.4 μm is more preferable in view of erase from the ends of the diffusion layers on both sides. According to the data of the semiconductor element having a channel length of 0.45 μm in FIG. 18, in particular, the electron injection is strongly carried out at the entire surface of the channel with erase of 1 μm, and a large threshold value shift occurs. That is, the electrons can be injected at an extremely high speed up to the distance of 0.45 μm per one side of the diffusion layer end, and as a result, high speed erase becomes possible if the channel length is smaller than or equal to 0.9 μm, or stable erase becomes possible at a lower voltage. In this regards, the channel length is most preferably smaller than or equal to 0.9 μm.

Therefore, the channel length is preferably smaller than or equal to 3.4 μm, and the channel length is more preferably smaller than or equal to 2.4 μm from the aspect of stability of repeated rewrite. The channel length of smaller than or equal to 0.9 μm is most preferable as a high performance semiconductor element enabling high speed erase can be obtained.

Thus, if the channel length is small, the distance from the electron injection position in erase to the middle of the channel is close, and the electron holes accumulated at the middle of the channel can be erased with a relatively low voltage, whereby the read current value of the erase state can be greatly increased with respect to the write state. Therefore, the memory having a wide window and a high reliability can be obtained.

If the channel length is smaller than 0.1 μm, the influence of the short channel effect becomes large, the variation among the semiconductor elements becomes large, and thus the channel length is preferably greater than or equal to 0.1 μm. The conditions of appropriate write/erase differ depending on the channel length, and the voltage of write/erase can be set lower the smaller the channel length. For instance, if the channel length is 0.5 μm, one diffusion layer region and the body region are set to the reference potential, −12 V to −16 V is applied to the gate electrode and −8 V to −12 V is applied to the other diffusion layer region as an example of the write condition; and the two diffusion layer regions are set to the reference potential, 12 V to 18 V is applied to the gate electrode, and 10 V to 12 V is applied to the body region as an example of the erase conditions.

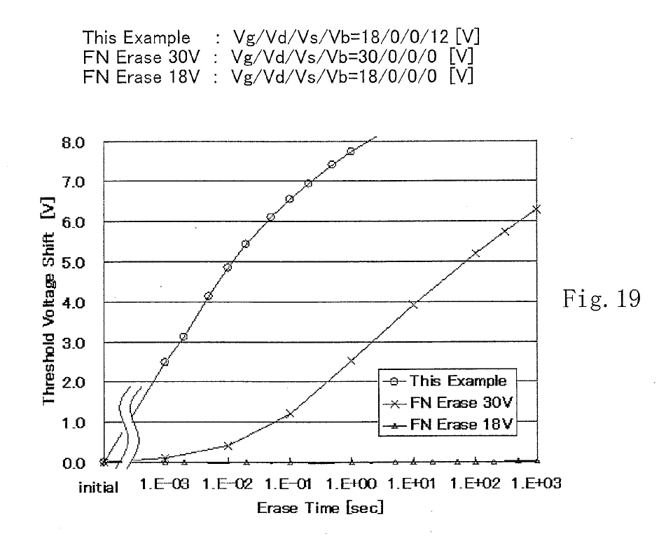

Therefore, erase of low voltage and high speed becomes possible compared to the erase method using FN tunneling and the like. FIG. 19 shows a graph of erase time dependence of the threshold value shift, where the characteristics (“this example” of the figure) of when erase is performed according to the above-described erase method, and the characteristics (“FN erase 30 V” and “FN erase 18 V” of the figure) of when erase is performed using electron injection by FN tunneling current are compared. With regards to the application voltage, 18 V is applied to the gate electrode and 12 V is applied to the body region with two diffusion layer regions at the reference potential in the erase method according to the second embodiment. In the case of “FN erase 30 V”, FN injection erase is performed at a higher voltage or by applying 30 V to the gate electrode with the two diffusion layer regions and the body region at the reference potential. Comparing both cases, erase significantly faster than the FN erase is realized although the erase of the second embodiment uses lower voltage. When FN erase is attempted (“FN erase 18 V”) by applying 18 V to the gate electrode, same as the second embodiment, the threshold value shift is barely recognized.

With respect to the write operation, write is barely performed at the voltage application (e.g., gate voltage of −30 V with respect to the reference potential) of the same level as the FN tunnel erase and the semiconductor element breaks if the voltage is raised higher. The write method of the second embodiment realizes the write operation at a lower voltage. Thus, the second embodiment realizes a high performance memory element capable of performing high speed write and erase at low voltage.

The second embodiment has a feature in being formed as a so-called P-channel semiconductor element, which aspect is extremely important in ensuring the window of write and erase. This will be described below.

In regards to write, the element of the present invention formed as the P-channel semiconductor element on the insulating substrate obtains a satisfactory write characteristic that cannot be obtained when formed as an N-channel semiconductor element, as described in the first embodiment. Furthermore, in regards to erase, satisfactory erase characteristics that cannot be obtained with the N-channel semiconductor element can be obtained as described below.

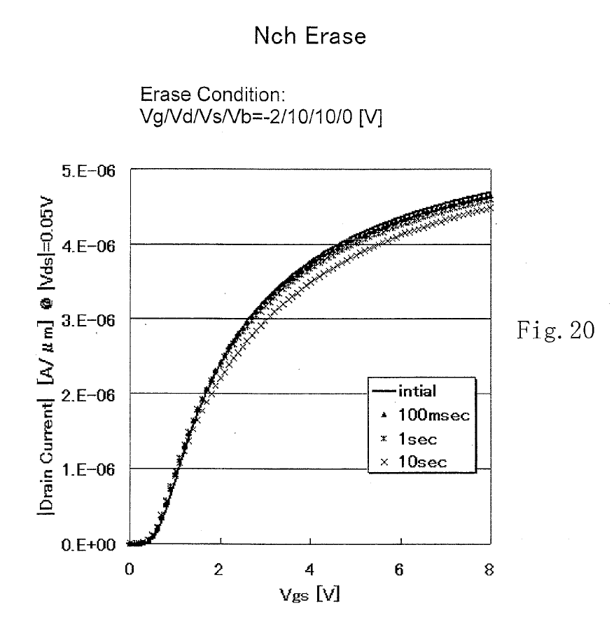

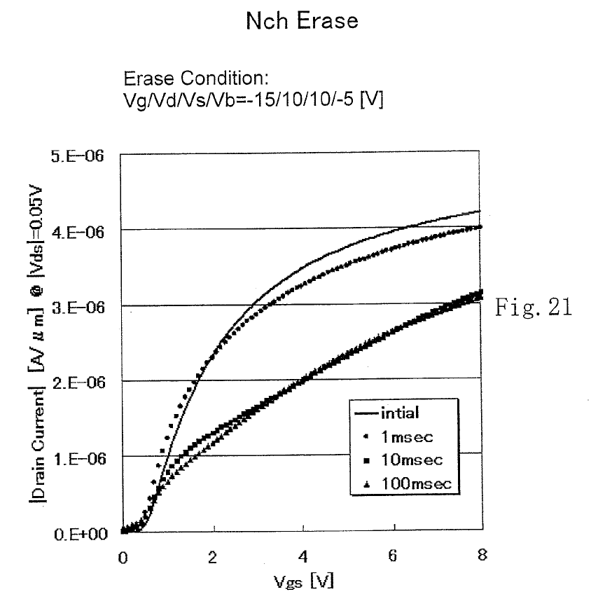

FIG. 20 is a view showing characteristics of when the erase voltage is applied with respect to the N-channel element having a structure similar to the memory element of the present invention. Similar structure means the same as the structure described in the first embodiment. As shown in FIG. 20, the threshold value shift surprisingly barely occurred even if the erase voltage is applied to a maximum of 10 seconds. The erase voltage is then increased, whereby the on-current decreased, as shown in FIG. 21. This means that the element has degraded. As apparent from FIGS. 20 and 21, it is difficult to erase the memory element of N-channel type. This is because in order to generate electron holes of an amount necessary for erase, voltage that is high to a certain extent needs to be applied to the junction part in terms of generating efficiency, whereby great amount of high energy electron holes are also generated in the process. Such high energy electron holes generally damage the gate insulating film and the boundary thereof, which may easily lead to degradation of device performance. In the case of an element using glass substrate, resin substrate, and the like, the substrate is inexpensive and low cost manufacturing becomes possible, but high temperature process processing cannot be performed in manufacturing. Thus, compared to the element formed using the high temperature process on the semiconductor substrate, the withstanding property to the high energy electron holes is low, and the element tends to be easily damaged. Therefore, in the N-channel element, degradation by damage precedes the erase itself by the electron hole injection through the application of the erase voltage, and as a result, the current lowers as shown in FIG. 21.

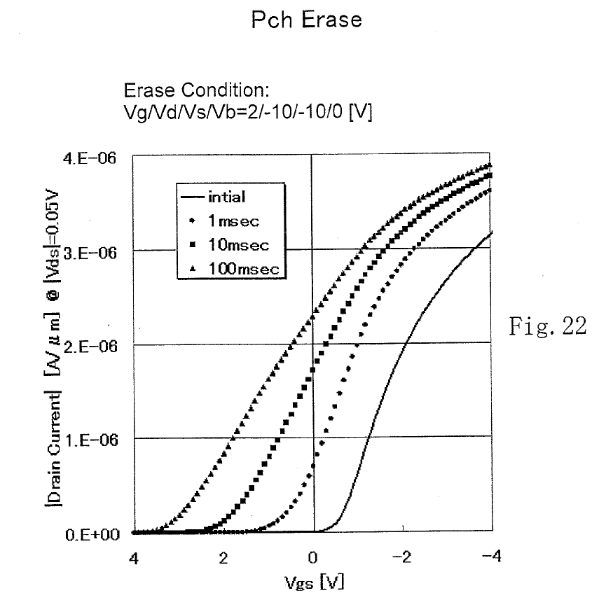

In the memory element of the present invention, which is a P-channel type, the threshold value shift of about 3 V is obtained when the erase time is 100 millisecond as shown with the erase characteristics in FIG. 22. The erase voltage in this case has an opposite sign with respect to the case of FIG. 20, but has the same absolute value. The absolute value of the application voltage to the two diffusion layer regions is 10 V, the absolute value of the gate voltage is 2 V, and the application voltage to the body region is 0 V. As apparent from FIGS. 20 to 22, the memory element of the present invention, which is a P-channel type, can greatly fluctuate the threshold value by erase and can enlarge the memory window as opposed to the N-channel type. The memory element of the present invention injects electrons and not electron holes in erase, and does not cause as great damage as in injecting electron holes.

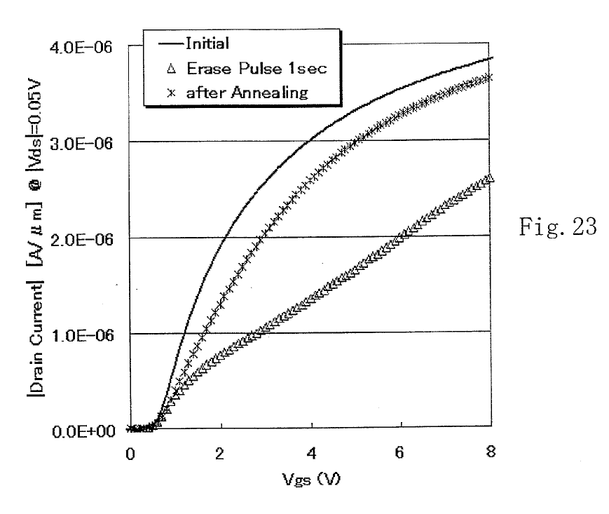

The result of performing the annealing treatment of a short time with respect to the N-channel semiconductor element (channel length of 0.7μm, channel width of 2.5 μm, gate insulating film configuration of 15 nm of top oxide, 20 nm of silicon nitride, and 10 nm of bottom oxide, erase voltage is −18 V for gate voltage, −12 V for body voltage, and 0 V for diffusion layer region) in which the on-current is reduced by applying a strong erase voltage is shown in FIG. 23. The annealing treatment is performed by placing the element in an annealing furnace, the temperature in the furnace being set to 250° C. First, in the state immediately after performing a strong erase voltage application, the semiconductor element is damaged by the high energy electron hole generated in time of erase, and thus the current is deteriorated, but the current is greatly recovered by performing the annealing treatment on the element. That is, the degradation in current by the injection of electron holes largely includes elements that can be recovered by thermal annealing.

Since the electron holes are injected in time of erase in the N-channel semiconductor element, degradation in current due to the damage leads to lowering in erase current. The lowering in the erase current narrows the window margin.

In the memory element of the second embodiment, which is a P-channel semiconductor element, the carriers to be injected in time of erase are electrons, and the memory element is less subjected to damage in electron injection than in electron hole injection. The electron holes are injected in write in the P-channel semiconductor element. This is the advantage of the second embodiment or the P-channel semiconductor element. That is, in write, the current is flowed between the source and the drain so that the semiconductor element generates heat, thereby raising the temperature. In the process of injecting electron holes with the assistance of such heat, the frequency of occurrence of the high energy electron holes is low, and the element is less likely to be damaged than in the erase voltage application of the N-channel semiconductor element.

Furthermore, even if the high energy electron holes are generated at one part and the semiconductor element is damaged in the write of the second embodiment, the temperature of the semiconductor element itself during the write operation is high, and thus at least one part of the damage is immediately recovered by the annealing effect.

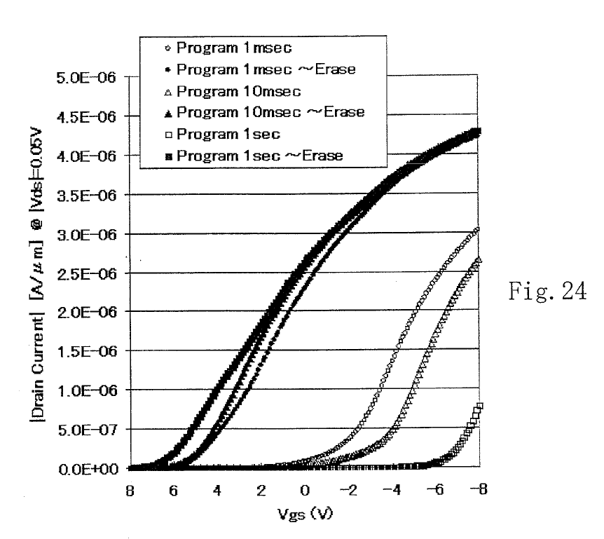

FIG. 24 shows characteristics of the write by various write times and the following erase. The write here is performed by applying 9 V to one diffusion layer region and the body region, −6 V to the gate electrode, and −3 V to the other diffusion layer region. The erase here is performed by applying −3 V to the two diffusion layer regions, 15 V to the gate electrode, and 9 V to the body region. As shown in FIG. 24, in the second embodiment, even if the write amount, that is, the electron hole injection amount is varied, substantially the same current is obtained by performing the erase thereafter, and current degradation barely occurs.

In other words, the high energy electron hole generally easily damages the gate insulating film and the boundary thereof and easily causes device degradation, but the electron hole injection in write of the second embodiment uses generated heat by the resistance of the semiconductor element itself, and generation of electron holes having high enough energy to cause damage is small in the write process, and thus device degradation is small. Furthermore, as the semiconductor element generates heat in write, the write operation itself provides the annealing effect, whereby even if one part is damaged by the electron hole injection in write in the second embodiment adopting a P-channel, an effect of self-recovering the damage is provided. Since the erase is performed by electron injection, the element is less likely to be subjected to damage. The memory element is realized which is formed on the insulating substrate such as glass substrate and resin substrate, and can be inexpensively manufactured without using a high temperature process, and furthermore which has strong resistance to damage degradation, and has a large memory window and high reliability.

As described in detail above, the memory element of the second embodiment is a memory element arranged on the insulating substrate, where the body region including a first diffusion layer region and the second diffusion layer region having a conductivity type of P-type, and the channel region sandwiched by the first diffusion layer region and the second diffusion layer region is arranged in the semiconductor layer arranged on the insulating substrate, the control element arranged contacting the body region, the charge accumulating film for covering the channel region, and the gate electrode positioned on the side opposite the body region with the charge accumulating film in between are arranged. The memory element is a so-called P-channel semiconductor element, where write is performed by injecting electron holes and erase is performed by injecting electrons, whereby the following advantages can be obtained.

In the second embodiment, the erase operation is performed by generating a reverse current between the body and the diffusion layer region by the control of the body potential, and generating high energy hot carriers. Thus, the erase can be performed at high speed at a relatively low voltage, but the hot carriers injected in erase are electrons and not electron holes as the second embodiment is formed as a P-channel element. If an N-channel element, on the other hand, the electron holes are injected in erase, but high energy electron holes tend to easily damage the element. Such damage lowers the read current. In the second embodiment, electrons are injected in erase, where injection of high energy electrons has less damage on the element compared to the injection of high energy electron holes. Therefore, the read current of the erase state is not greatly lowered. Generally, the read current difference in the write state and the erase state, or a so-called window is large the larger the read current of the erase state, and is preferable as a reliability as the memory is high. The semiconductor element of the second embodiment in which the element is less likely to be damaged in erase and in which lowering of read current is less likely to occur has the following advantages.

The electron hole injection is performed in the write, in which case, the element generates heat by flowing current between the diffusion layer regions, and the element temperature rises since the lower part is an insulating substrate and has high heat insulation performance. The main mechanism of electron hole injection in the memory element of the second embodiment is assisted by such heat, and interposition of high energy electron holes that may damage the element is small. Furthermore, even if high energy electron holes are generated at one part and the element is damaged, the damage can be recovered by the annealing effect since the temperature of the element itself is rising, and consequently, the electron hole injection of small damage can be realized. As the damage is small, the charges can be held over a long period of time without greatly affecting the charge holding ability.

Therefore, the memory element of the second is a memory element of high reliability that characteristically has a wide window margin by adopting the above-described configuration. The damage is also small in write and in erase, and thus the element has a wide window margin even after repeated rewrite, and furthermore, holding for an extremely long time can be realized.

In particular, when forming the memory element of the second embodiment and the peripheral circuit for driving the memory element on the same insulating substrate, a merit in being inexpensively manufactured is obtained since the peripheral circuit is configured by TFT, but each element configuring the peripheral circuit has characteristic variation. Thus, the dead zone of the read circuit also becomes large. From this aspect, it is an extremely important advantage in terms of operation reliability that the window margin is large as in the memory element of the second embodiment.

As described in the first embodiment, the thinness of the gate insulating film suppresses generation of high energy hot carriers in the vicinity of the drain end in write. Therefore, the damage on the semiconductor element can be suppressed. As described above, recovery of damage of a certain extent is possible by the generated heat in write, but the damage accumulates by the repeated rewrite unless the damage is completely recovered, which may affect the reliability of the device. Therefore, the generation of high energy hot carriers that provides a great damage is preferably suppressed as much as possible. From this aspect, the gate insulating film is preferably thin. The gate electric field can be efficiently acted on the channel part in erase by thinning the gate insulating film. As the generated carriers are more strongly attracted to the gate electrode side, the erase efficiency can be enhanced. Therefore, the gate insulating film is preferably thinned to an extent device breakage or excessive variation in semiconductor elements do not occur.

### Third Embodiment

A third embodiment of the present invention uses a memory element shown in first and second embodiments in a liquid crystal display device.

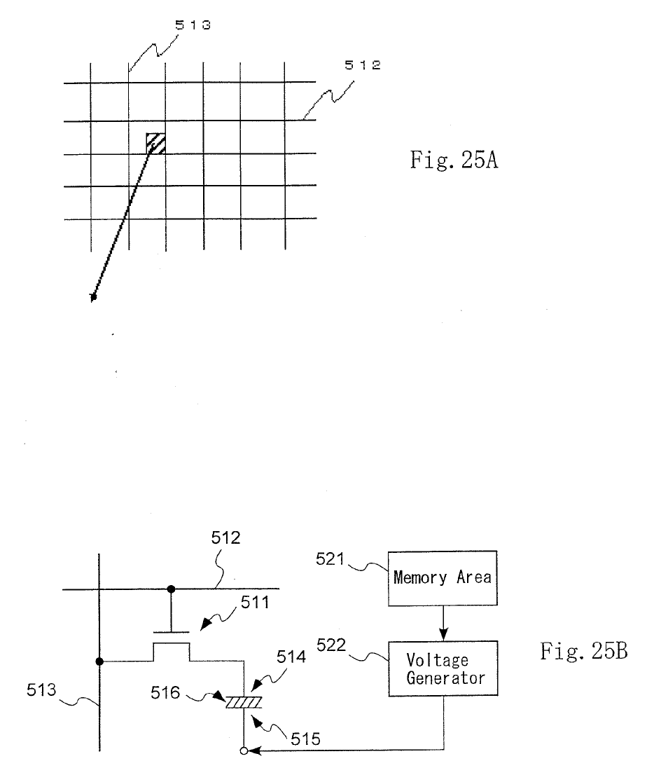

The liquid crystal display device is configured with the liquid crystals sandwiched between the pair of substrates, scanning lines 512 and signal lines 513 are formed on one substrate as shown in FIG. 25A, and a drive circuit 510 for selectively driving a pixel electrode corresponding to one pixel is arranged, one pixel being a region surrounded by the scanning line 512 and the signal line 513. Each pixel electrode faces the opposite electrode formed on the other substrate with the liquid crystals interposed in between, and selectively drives one pixel.

The third embodiment has a feature in that the memory element shown in the first embodiment is formed on the panel substrate of the liquid crystal display device. In this case, the memory element of the present invention is used as an element for accumulating image information to be provided to the voltage generator for applying voltage to the opposite electrode of the liquid crystal display device.

More specifically, as shown in FIG. 25B, the scanning line 512 is connected to a gate electrode of a pixel TFT 511, the signal line 513 is connected to one diffusion layer region of the pixel TFT 511, and a pixel electrode 514 is connected to the other diffusion layer region. The pixel electrode 514 faces an opposite electrode 515 of the common panel by way of a liquid crystal 516. A predetermined voltage generated by a voltage generator 522 is applied to the opposite electrode 515. The voltage generated by the voltage generator 522 is determined based on the image information stored in a memory area 521 arranged in the memory element of the present invention.

The voltage generated by the voltage generator 522 is applied to the opposite electrode 515 to suppress flickering of the screen, where the voltage value is to be adjusted for every panel. The voltage adjustment is generally performed by adjusting a variable resistor externally attached to the panel. The cost of the outside component itself and the attachment cost of the outside component can be reduced by arranging the memory element of the first embodiment of the present invention. The examination cost can be reduced since automation of the adjustment can be facilitated. Furthermore, the memory element of the present invention is advantageous in reducing cost since the structure of the gate insulating film is simple, and the necessary number of processes is small.

### Fourth Embodiment

A fourth embodiment of the present invention is a display device equipped with the memory element shown in the first and the second embodiments. The display device may be a liquid crystal panel, an organic EL panel, or the like.

The display device further includes a voltage output circuit which is input with digital information and which outputs a voltage defined by the digital information to the opposite electrode, and a DA converter for converting digital tone data to analog tone signal on the panel substrate, where a feature lies in that data defining the correlation between the digital tone data and the voltage of the analog tone signal is stored in the memory element of the first embodiment.

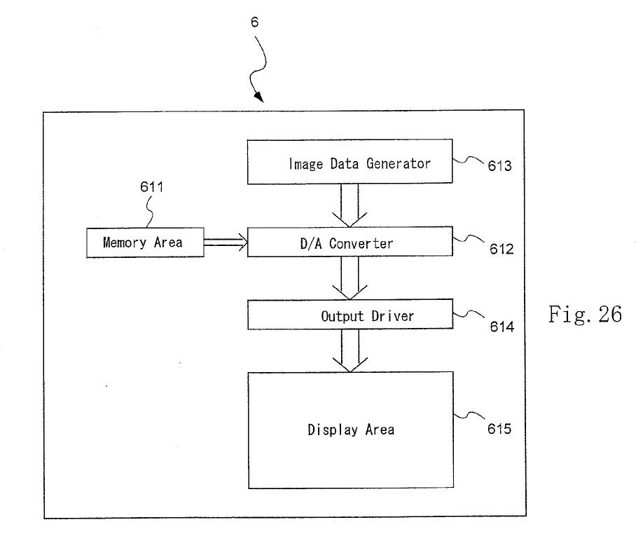

More specifically, as shown in FIG. 26, an image data generator 613 is arranged in a display device 6, and display data, which is a digital signal, is provided to a DA converter 612. The DA converter 612 converts the display data, which is a digital signal, to an analog signal, and provides the same to a display area 615 via an output driver 614. In this case, the correlation between the digital tone data and the voltage of the analog tone signal needs to be adjusted in the DA converter 612 to naturally reproduce the colors of the image to be displayed on the display area. This correlation is to be adjusted for every panel. The correlation between the digital tone data and the voltage of the analog tone signal is stored in a memory area 611 including the memory element of the present invention.

The correlation between the digital tone data and the voltage of the analog tone signal is generally stored in a non-volatile memory chip externally attached to the panel. The cost of the outside component itself and the attachment cost of the outside component can be reduced by arranging the memory element of the present invention. The examination cost can be reduced since automation of the adjustment can be facilitated. Furthermore, the memory element of the present invention is advantageous in reducing cost since the structure of the gate insulating film is simple, and the necessary number of processes is small.

### Fifth Embodiment

A fifth embodiment of the present invention is a receiver equipped with the display device including the memory element shown in the first and the second embodiments, and has a feature in that a display device is arranged, and a receiving circuit for receiving an image signal and an image signal circuit for providing the image signal received by the receiving circuit to the display device, and a memory element to store data necessary for generating the image signal are formed on the panel substrate of the display device.

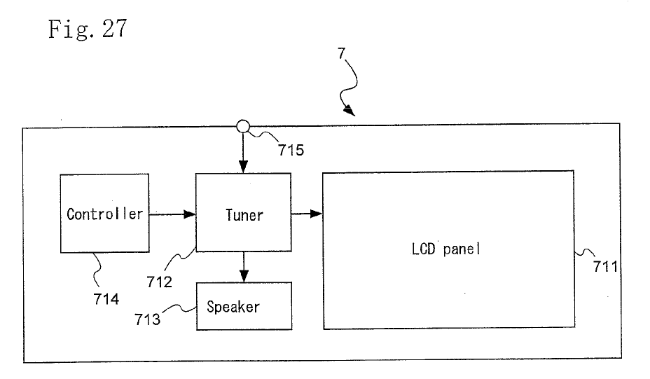

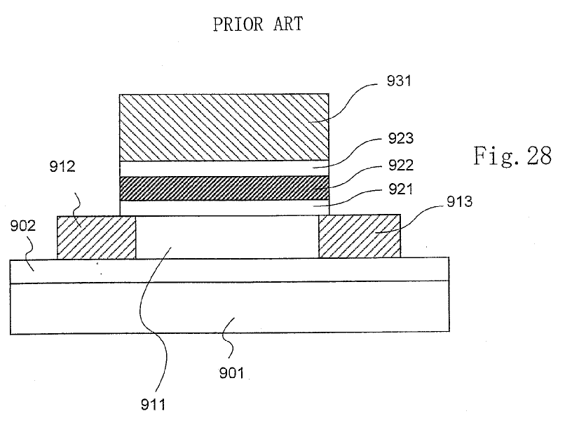

Specifically, as shown in FIG. 27, a receiver 7 includes a display device (liquid crystal display panel) 711, a tuner 712, a speaker 713, a controller 714, and an antenna terminal 715. FIG. 21 shows a format of receiving a radio signal with an antenna, but when receiving the signal by wire, the antenna terminal is replaced with a cable connection terminal and the tuner is replaced with a signal receiving unit. The display device 711 includes the memory element of the present invention. The non-volatile memory arranged in the display device 711 can store a voltage value to be applied to the opposite electrode of the liquid crystal panel, the correlation between the digital tone data and the voltage of the analog tone signal, and the like. Furthermore, an encrypted signal can be transmitted to the display device, and the encryption can be decrypted at the display panel to strengthen the information security, where the key of encryption in this case can be stored in the memory element arranged in the display device. A high function receiver can be realized at low cost by arranging such display device.

What is claimed is:

1. A semiconductor element comprising:
a semiconductor layer arranged on an insulating substrate;
a first diffusion layer region and a second diffusion layer region having a conductivity type of P-type arranged in the semiconductor layer;
a charge accumulating film for covering at least a channel region between the first diffusion layer region and the second diffusion layer region and being injected with charges from the channel region; and
a gate electrode positioned on a side opposite to the channel region with the charge accumulating film in between.

2. The semiconductor element according to claim 1, wherein the insulating substrate has a thermal conductivity of between 0.1 and 9 W/m·K.

3. The semiconductor element according to claim 1, wherein the semiconductor layer arranged on the insulating substrate has at least an upper surface of the channel region formed substantially flat.

4. The semiconductor clement according to claim 1, wherein the charges injected to the charge accumulating film are charges injected so that the charges are distributed substantially symmetric in the charge accumulating film by being subjected to assistance of heat generated in the channel region by current when the current flows from the first diffusion layer region to the second diffusion layer region through the channel region.

5. The semiconductor element according to claim 1, wherein the charges injected to the charge accumulating film are charges from carrier generation over an entire surface of the channel region subjected to assistance of heat generated in the channel region by current when the current flows from the first diffusion layer region to the second diffusion layer region through the channel region.

6. The semiconductor element according to claim 1, wherein the charges injected to the charge accumulating film are charges trapped in the charge accumulating film in the vicinity of at least the first diffusion layer region by being subjected to assistance of heat generated in the channel region by current when the current flows from the first diffusion layer region to the second diffusion layer region through the channel region.

7. The semiconductor element according to claim 1, wherein in a state charges are injected in the charge accumulating film, a difference between a threshold value of when a reference potential is applied to the first diffusion layer region and a negative voltage is applied to the second diffusion layer region, and a threshold value of when the reference potential is applied to the second diffusion layer region and a negative voltage is applied to the first diffusion layer region is smaller than or equal to 10%.

8. The semiconductor element according to claim 1, further comprising an inter-layer insulating film formed on the semiconductor layer and the gate electrode.

9. The semiconductor element according to claim 8, wherein at least one part of the inter-layer insulating film consists of resin.

10. The semiconductor element according to claim 1, wherein the channel region has a channel width of between 0.5 μm and 100 μm.

11. The semiconductor element according to claim 1, wherein the channel region has a channel width of between 2 μm and 20 μm.

12. The semiconductor element according to claim 1, wherein the charge accumulating film has a stacked structure including at least a first insulating film, a charge accumulating film having a charge accumulating ability, and a second insulating film.

13. The semiconductor element according to claim 12, wherein the charge accumulating film having the charge accumulating ability is a nitride film or a high dielectric film.

14. The semiconductor element according to claim 1, wherein the semiconductor layer is an island semiconductor layer formed on the insulating substrate.

15. The semiconductor element according to claim 1, wherein the semiconductor layer has a film thickness of between 30 nm and 150 nm.

16. The semiconductor element according to claim 1, wherein the insulating substrate is a glass substrate having a thermal conductivity of between 0.5 and 2 W/m·K.

17. The semiconductor element according to claim 1, wherein the insulating substrate is a resin substrate having a thermal conductivity of between 0.1 and 2 W/m·K.

18. The semiconductor element according to claim 1, wherein the semiconductor layer includes a contact region having a conductivity type of N-type, and the contact region contacts a control terminal.

19. The semiconductor element according to claim 1, wherein the channel region has a channel length of between 0.1 μm and 3.4 μm.

20. The semiconductor element according to claim 18, wherein a semiconductor layer region of lower concentration than an impurities concentration of the contact region is formed between the contact region, and the first diffusion layer region and the second diffusion layer region.

21. The semiconductor element according to claim 20, wherein the gate electrode is arranged on the semiconductor layer region of low concentration.

22. The semiconductor element according to claim 1, further comprising a display device on the insulating substrate.

23 The semiconductor element according to claim 1, further comprising a heating means for heating the insulating substrate.

24. A liquid crystal display device comprising:
a liquid crystal display device including,
scanning lines and signal lines arranged in a matrix form,
a drive circuit for selectively driving a pixel electrode corresponding to one pixel, the one pixel being a region surrounded by the scanning line and the signal line, and
a liquid crystal interposed between the pixel electrode and an opposite electrode facing thereto; and
a liquid crystal drive circuit, including,
a voltage output circuit, input with digital information, for outputting a voltage defined by the digital information to the opposite electrode,
a DA converter for converting digital tone data to an analog tone signal, and
a storage circuit including a semiconductor element for storing data defining a correlation between the digital tone data and a voltage of the analog tone signal, the semiconductor element being the semiconductor element according to claim 1, on a panel substrate.

25. A receiver comprising:
a display device;
a receiving circuit for receiving an image signal;
an image signal circuit for providing the image signal received by the receiving circuit to the display device; and
a storage circuit including a semiconductor element for storing data necessary for generating the image signal,
the semiconductor element being the semiconductor element according to claim 1.

26. A semiconductor device comprising:
the semiconductor element according to claim 1;
a first voltage application circuit connected to the first diffusion layer region of the semiconductor element by way of a first switching element;
a second voltage application circuit connected to the second diffusion layer region of the semiconductor element by way of a second switching element; and
a third voltage application circuit connected to the gate electrode of the semiconductor element by way of a third switching element.

27. The semiconductor device according to claim 26, wherein the second voltage application circuit and the third voltage application circuit output voltages lower than a voltage output by the first voltage application circuit.

28. The semiconductor device according to claim 26, wherein the third voltage application circuit outputs a voltage lower than a voltage output by the second voltage application circuit.

29. The semiconductor device according to claim 26, further comprising a fourth voltage application circuit connected to a body region of the semiconductor element by way of a fourth switching element.

30. The semiconductor device according to claim 29, wherein the third voltage application circuit and a fourth voltage application circuit output voltages higher than a voltage output by the first voltage application circuit.

31. The semiconductor device according to claim 29, wherein the third voltage application circuit outputs a voltage higher than a voltage output by a fourth voltage application circuit.

32. A driving method of a semiconductor element of, using the semiconductor element according to claim 1, applying a negative voltage to the second diffusion layer region and the gate electrode with respect to a reference voltage applied to the first diffusion layer region, generating a current in the channel region and generating heat, and injecting electron holes to the charge accumulating film.

33. The driving method of the semiconductor element according to claim 32, wherein the negative voltage applied to the gate electrode has a larger absolute value than the negative voltage applied to the second diffusion layer region.

34. The driving method of the semiconductor element according to claim 32, wherein electrons are injected to the charge accumulating film by applying a positive voltage to the gate electrode and the body region with respect to the reference voltage applied to the first diffusion layer region.

35. The driving method of the semiconductor element according to claim 32, wherein electrons are injected to the charge accumulating film by applying a positive voltage to the gate electrode and the body region with a potential of the second diffusion layer region at substantially the same potential with respect to the reference voltage applied to the first diffusion layer region.

36. The driving method of the semiconductor element according to claim 35, wherein a positive voltage applied to the gate electrode is higher than a positive voltage applied to the body region.
